(19) United States
(12) Patent Application Publication
(10) Pub. No.: US 2025/0336575 A1
(43) Pub. Date: Oct. 30, 2025

(54) PACKAGED ELECTRICAL DEVICES AND RELATED METHODS

(71) Applicant: Bourns, Inc., Riverside, CA (US)

(72) Inventors: Oscar ULLOA ESQUIVEL, Heredia (CR); Javier VILLEGAS CALDERON, Heredia (CR); Patrocinio Ryan REYES, Riverside, CA (US); Minh NGUYEN, Garden Grove, CA (US); Gordon Lee BOURNS, II, Riverside, CA (US); Gordon L. BOURNS, Riverside, CA (US)

(21) Appl. No.: 19/204,549

(22) Filed: May 11, 2025

Related U.S. Application Data
(63) Continuation of application No. PCT/US2023/079609, filed on Nov. 14, 2023.
(60) Provisional application No. 63/425,055, filed on Nov. 14, 2022.

(51) Int. Cl. H01C 1/14; H01C 7/10; H01C 17/28

(52) U.S. Cl. CPC H01C 1/14; H01C 7/10; H01C 17/28

(57) ABSTRACT

In some embodiments, a packaged device can include an electrical device having first and second electrodes implemented on opposite sides of a body. The electrical device can be sandwiched between first and second terminal assemblies, with the first and second terminal assemblies being configured to provide the packaged device with a surface mount device (SMD) format, thereby allowing the electrical device to be easily mounted on a surface of a circuit board.

### CROSS-REFERENCE TO RELATED APPLICATION(S)

This application is a continuation of International Application No. PCT/US2023/079609 filed Nov. 14, 2023, entitled PACKAGED ELECTRICAL DEVICES AND RELATED METHODS, which claims priority to U.S. Provisional Application No. 63/425,055 filed Nov. 14, 2022, entitled PACKAGED ELECTRICAL DEVICES AND RELATED METHODS, the benefits of the filing dates of which are hereby claimed and the disclosures of which are hereby expressly incorporated by reference herein in their entirety.

### BACKGROUND

### Field

The present disclosure relates to packaged electrical devices and related methods.

### Description of the Related Art

An electrical device is commonly implemented in packaged format to allow easy mounting onto a circuit board. For example, a packaged electrical device having a surface mount device (SMD) format is configured to allow easy mounting of the device on a surface of a circuit board.

### SUMMARY

In some implementations, the present disclosure relates to a packaged device that includes an electrical device having first and second electrodes implemented on opposite sides of a body, a first terminal assembly including a substrate having an inner side and an outer side, a conductive feature on the inner side of the substrate and first and second terminals on the outer side of the substrate, and a second terminal assembly including a substrate having an inner side and an outer side, a conductive feature on the inner side of the substrate and first and second terminals on the outer side of the substrate. The electrical device is sandwiched between the first and second terminal assemblies to provide first and second spaces each defined between the inner sides of the substrates of the first and second terminal assemblies and a respective lateral side of the electrical device, such that the conductive features of the first and second terminal assemblies are electrically connected with the first and second electrodes of the electrical device, respectively. A set of conductive pins or wires including a first conductive pin or wire extend through the first space to join the respective portions of the first and second terminal assemblies, such that the first electrode of the electrical device is electrically connected to the first terminal of the first terminal assembly and the second terminal of the second terminal assembly through the conductive feature of the first terminal assembly and the first conductive pin or wire. The set of conductive pins or wires further include a second conductive pin or wire extending through the second space to join the respective portions of the first and second terminal assemblies, such that the second electrode of the electrical device is electrically connected to the second terminal of the first terminal assembly and the first terminal of the second terminal assembly through the conductive feature of the second terminal assembly and the second conductive pin or wire.

In some embodiments, the electrical device can further include a third electrode implemented on the side of the body with the first electrode, and the first terminal assembly can further include a second conductive feature on the inner side of the substrate and a third terminal on the outer side of the substrate. The second terminal assembly can further include a third terminal on the outer side of the substrate, and the set of pins or wires can further include a third conductive pin or wire extending through the first space to join the respective portions of the first and second terminal assemblies, such that the third electrode of the electrical device is electrically connected to the third terminal of the first terminal assembly and the third terminal of the second terminal assembly through the second conductive feature of the first terminal assembly and the third conductive pin or wire.

In some embodiments, the first and second spaces can be parts of a contiguous space that surrounds the electrical device, such that the first and second spaces are at or near opposing ends of the packaged device. In some embodiments, the packaged device can further include an electrical insulator filler material that fills at least portions of the contiguous space to substantially encapsulate the lateral periphery of the electrical device and the set of conductive pins or wires.

In some embodiments, the first and second electrodes of the electrical device can be substantially parallel to each other, and the substrates of the first and second terminal assemblies can also be substantially parallel to each other. In some embodiments, each of the substrates of the first and second terminal assemblies can have a rectangular shape. The conductive feature of each of the first and second terminal assemblies can include an electrode-contact portion and an edge portion in electrical contact with the electrode-contact portion, with the edge portion implemented to be at or near a first edge of the respective substrate, and the electrode-contact portion implemented to be laterally closer to a center of the substrate. The edge portion can include a hole configured to allow the respective conductive pin or wire to pass therethrough. The hole can extend through the substrate and the respective terminal on the other side of the substrate. The hole can include a conductive wall.

In some embodiments, the conductive feature can have a rectangular shape with one edge being at or near the first edge. In some embodiments, the electrode-contact portion of the conductive portion can be dimensioned to promote desired lateral positioning of the electrical device during a mounting operation. The electrode-contact portion can include a shape that is similar to a shape of the respective electrode of the electrical device. The electrode of the electrical device can have a circular shape, and the electrode-contact portion of the conductive feature can include at least a portion of a circular boundary.

In some embodiments, the set of conductive pins or wires can further include a third conductive pin or wire extending through the first space to provide an electrical connection similar to the first conductive pin or wire, and a fourth conductive pin or wire extending through the second space to provide an electrical connection similar to the second conductive pin or wire. The first, second, third and fourth conductive pins or wires can be positioned near respective corners of the rectangular shaped substrates. Some or all of the first, second, third and fourth conductive pins or wires can include respective ends that extend beyond respective terminal(s) and configured to support mounting of the packaged device on a circuit board and/or inspection of the mounted packaged device. The ends of the conductive pins or wires configured to support mounting of the packaged device can include an extension along the same direction of the respective conductive pin or wire between the first and second terminal assemblies, with the extension dimensioned to allow formation of electrical contacts with a respective terminal on the side opposite from the mounting side of the circuit board. The first terminal assembly of the packaged device can face the mounting side of the circuit board.

In some embodiments, the ends of the conductive pins or wires configured to support mounting of the packaged device can include an L-shaped extension with respect to the direction of the respective conductive pin or wire between the first and second terminal assemblies. The edge of the packaged device can include the first and second terminals of each terminal assembly faces the mounting side of the circuit board. The L-shaped extension can be dimensioned to allow formation of electrical contacts with a respective terminal on the mounting side of the circuit board. The L-shaped extension can be dimensioned to allow formation of electrical contacts with a respective terminal on the side opposite from the mounting side of the circuit board.

In some embodiments, the packaged device can further include an insulator sleeve that substantially covers the portion of each conductive pin or wire in the respective space. The insulator sleeve can be configured to reduce and/or mitigate thermal expansion mismatch associated with the respective conductive pin or wire, and/or to provide improved handling of a voltage operating condition.

In some embodiments, each terminal assembly can further include an electrical insulator layer implemented on the outer side of the respective substrate to cover some or all of an area between the respective terminals. The electrical insulator layer can include a surface configured to allow marking thereon. The electrical insulator layer can include a solder mask material.

In some embodiments, some or all edges of each substrate can include a score feature surface resulting from singulation of the packaged device from an array of similar packaged devices.

In some embodiments, the first and second terminal assemblies can be configured substantially the same, such that when the electrical device is sandwiched between the first and second terminal assemblies, one terminal assembly is rotated approximately 180 degrees with respect to the other terminal assembly.

In some implementations, the present disclosure relates to a method for fabricating a packaged device. The method includes forming or providing an electrical device having first and second electrodes implemented on opposite sides of a body, forming or providing a first terminal assembly including a substrate having an inner side and an outer side, a conductive feature on the inner side of the substrate and first and second terminals on the outer side of the substrate, and forming or providing a second terminal assembly including a substrate having an inner side and an outer side, a conductive feature on the inner side of the substrate and first and second terminals on the outer side of the substrate. The method further includes assembling the electrical device and the first and second terminal assemblies such that the electrical device is sandwiched between the first and second terminal assemblies to provide first and second spaces each defined between the inner sides of the substrates of the first and second terminal assemblies and a respective lateral side of the electrical device, such that the conductive features of the first and second terminal assemblies are electrically connected with the first and second electrodes of the electrical device, respectively. The method further includes installing a set of conductive pins or wires including a first conductive pin or wire extending through the first space to join the respective portions of the first and second terminal assemblies, such that the first electrode of the electrical device is electrically connected to the first terminal of the first terminal assembly and the second terminal of the second terminal assembly through the conductive feature of the first terminal assembly and the first conductive pin or wire. The set of conductive pins or wires further includes a second conductive pin or wire extending through the second space to join the respective portions of the first and second terminal assemblies, such that the second electrode of the electrical device is electrically connected to the second terminal of the first terminal assembly and the first terminal of the second terminal assembly through the conductive feature of the second terminal assembly and the second conductive pin or wire.

In some implementations, the present disclosure relates to a method for fabricating packaged devices. The method includes providing or forming first and second terminal assembly panels each having an array of units, with each unit including a substrate having an inner side and an outer side, a conductive feature on the inner side, and first and second terminals on the outer side of the substrate. The method further includes mounting an electrical device having first and second electrodes implemented on opposite sides of a body on each unit of the first terminal assembly panel, such that the first electrode of the electrical device is electrically connected to the conductive feature of the respective unit of the first terminal assembly panel. The method further includes mounting the second terminal assembly panel over the array of electrical devices, such that the second electrode of each electrical device is electrically connected to the conductive feature of the respective unit of the second terminal assembly panel. The mounting of the second terminal assembly panel results in each electrical device being sandwiched between the respective units of the first and second terminal assembly panels to provide first and second spaces each defined between the inner sides of the respective substrates and a respective lateral side of the electrical device. The method further includes installing a set of conductive pins or wires for each unit, with the set of conductive pins or wires including a first conductive pin or wire extending through the first space to join the respective portions of the first and second terminal assemblies, such that the first electrode of the electrical device is electrically connected to the first terminal of the first terminal assembly and the second terminal of the second terminal assembly through the conductive feature of the first terminal assembly and the first conductive pin or wire. The set of conductive pins or wires further includes a second conductive pin or wire extending through the second space to join the respective portions of the first and second terminal assemblies, such that the second electrode of the electrical device is electrically connected to the second terminal of the first terminal assembly and the first terminal of the second terminal assembly through the conductive feature of the second terminal assembly and the second conductive pin or wire. The method further includes singulating the sandwich-pair of units to provide a plurality of individual sandwich-pair of units.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows a mounting side of a surface mount device (SMD) having a body and first and second terminals.

FIG. 1B shows a side view of the SMD of FIG. 1A.

FIG. 1C shows the SMD of FIGS. 1A and 1B mounted on a mounting surface of a circuit boards.

FIG. 2 depicts a packaged device that includes an electrical device having first and second electrodes implemented on opposite sides of a body.

FIG. 3A shows that in some embodiments, an electrical device that can be utilized for a packaged device as described herein can include electrodes with each electrode having a lateral dimension that is approximately the same as the corresponding lateral dimension of the body.

FIG. 3B shows that in some embodiments, an electrical device that can be utilized for a packaged device as described herein can include electrodes with each electrode having a lateral dimension that is greater than the corresponding lateral dimension of the body.

FIG. 4A shows a side sectional view of an example of a terminal assembly that can be utilized to form a packaged device as described herein.

FIG. 4B shows an outer side plan view of the terminal assembly of FIG. 4A.

FIG. 4C shows an inner side plan view of the terminal assembly of FIG. 4A.

FIG. 5A shows a plan view of an inner side of another example of a terminal assembly that can be utilized to form a packaged device as described herein.

FIG. 5B shows a plan view of an outer side of the terminal assembly of FIG. 5A.

FIG. 5C shows a side sectional view of the terminal assembly along the section indicated on the plan view of FIG. 5A.

FIG. 5D shows a side sectional view of the terminal assembly along the section indicated on each of the plan views of FIGS. 5A and 5B.

FIGS. 6A to 6D show an example process for fabricating a terminal assembly, such as the terminal assembly of FIG. 4.

FIG. 6E shows an enlarged view of regions indicated in FIG. 6D.

FIG. 7A shows an unassembled view of an electrical device and first and second terminal assemblies.

FIG. 7B shows an assembled view of the parts shown in FIG. 7A.

FIG. 7C shows an assembly resulting from placing of a conductive pin through each through-substrate hole of the first terminal assembly and the corresponding through-substrate hole of the second terminal assembly.

FIG. 7D shows an enlarged view of the portions indicated in FIG. 7C, where the pins or wires are not swaged, but inserted through the respective holes with conductive walls.

FIG. 7E shows an enlarged view of the portions indicated in FIG. 7C. where each pin or wire can be swaged to provide either or both of shoulder structures of the pin or wire at respective surface(s) of the terminal assembly.

FIG. 7F shows that in some embodiments, a packaged device having one or more features as described herein can include an insulator sleeve implemented to cover each conductive pin or wire between the two terminal assemblies.

FIG. 8A shows that in some embodiments, a packaged device which is similar to the example of FIG. 7C can include an open space on the periphery of the electrical device sandwiched between two terminal assemblies.

FIG. 8B shows that in some embodiments, some or all of the space of FIG. 8A can be optionally filled with an electrical insulator material such as an epoxy or elastic material, a high temperature silicone sealer, or some combination thereof.

FIGS. 9A to 9D show an example process that can be utilized to fabricate an array of terminal assemblies.

FIGS. 9E to 9H show examples related to an assembly that includes an array of fabricated units similar to the array of fabricated units of the assembly of FIG. 9D.

FIG. 10A shows that in some embodiments, an electrical device can be positioned on each unit of a first assembly such as the assembly of FIG. 9D.

FIG. 10B shows that in some embodiments, a second assembly can be positioned over the array of electrical devices.

FIG. 10C shows that in some embodiments, conductive pins or wires can be inserted into respective through-substrate hole of each pair corresponding units of the first and second assemblies.

FIG. 10D shows that in some embodiments, spaces in the assembly of FIG. 10C can be filled similar to the example of FIG. 8B.

FIG. 11A shows an assembly that is substantially the same as the assembly of FIG. 10C.

FIG. 11B shows that an array of un-singulated units can be singulated utilizing, for example, sawing, cutting or the like, to yield a plurality of packaged devices.

FIG. 12A shows an assembly that is substantially the same as the assembly of FIG. 10D.

FIG. 12B shows that an array of un-singulated units can be singulated utilizing, for example, sawing, cutting or the like, to yield a plurality of packaged devices.

FIG. 13A shows a packaged device as described herein, without an electrical insulator filler.

FIG. 13B shows a packaged device, also as described herein, with an electrical insulator filler.

FIG. 13C shows an edge configuration that can be implemented for a packaged device such as the packaged device of FIG. 13A or the packaged device of FIG. 13B.

FIG. 14A shows an electrical device that can be included in the packaged devices of FIGS. 13A and 13B, where the electrical device is implemented as a combination of a metal-oxide varistor (MOV), a gas discharge tube (GDT), and another MOV.

FIG. 14B shows another electrical device that can be included in the packaged devices of FIGS. 13A and 13B, where the electrical device is implemented as a combination of an MOV, a GDT, and another MOV.

FIG. 14C shows another electrical device that can be included in the packaged devices of FIGS. 13A and 13B, where the electrical device is implemented as a GDT.

FIG. 14D shows another electrical device that can be included in the packaged devices of FIGS. 13A and 13B, where the electrical device is implemented as a GDT.

FIG. 15 shows another example shape of a conductive feature that can be implemented on an inner side of a substrate of a terminal assembly.

FIG. 16 shows a side view of an electrical device having a body with opposing sides, and two electrodes implemented on one side, and a third electrode implemented on the opposing side.

FIG. 17A shows an inner side of a first terminal assembly that can be utilized to provide contacts with the two electrodes of the electrical device of FIG. 16.

FIG. 17B shows an outer side of the first terminal assembly of FIG. 17A.

FIG. 17C shows an inner side of a second terminal assembly that can be utilized to provide contact with the electrodes of the electrical device of FIG. 16.

FIG. 17D shows an outer side of the second terminal assembly of FIG. 17C.

FIG. 18A shows a packaged device from an edge side of the first terminal assembly of FIGS. 17A and 17B.

FIG. 18B shows the same packaged device from another edge side of the first terminal assembly of FIGS. 17A and 17B.

FIG. 19 shows a packaged device having one or more features as described herein, including an end configuration for some or all of the conductive pins or wires.

FIGS. 20A to 20D show non-limiting examples of the end configuration of FIG. 19.

FIG. 21A shows a plan view of a mounting configuration from above a circuit board.

FIG. 21B shows a side view as indicated in FIG. 21A.

FIG. 21C shows an end view as indicated in FIG. 21A.

FIG. 22A shows a plan view of another mounting configuration from above a circuit board.

FIG. 22B shows a side view as indicated in FIG. 22A.

FIG. 22C shows an end view as indicated in FIG. 22A.

FIG. 23A shows a plan view of another mounting configuration from above a circuit board.

FIG. 23B shows a side view as indicated in FIG. 23A.

FIG. 23C shows an end view as indicated in FIG. 23A.

FIG. 24A shows a plan view of another mounting configuration from above a circuit board.

FIG. 24B shows a side view as indicated in FIG. 24A.

FIG. 24C shows an end view as indicated in FIG. 24A.

### DETAILED DESCRIPTION OF SOME EMBODIMENTS

The headings provided herein, if any, are for convenience only and do not necessarily affect the scope or meaning of the claimed invention.

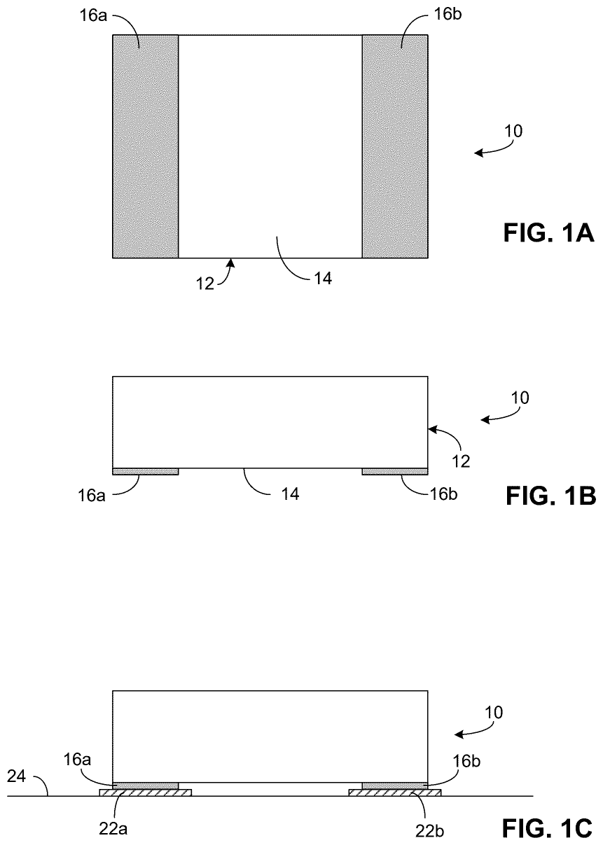

FIG. 1A shows a mounting side 14 of a surface mount device (SMD) 10 having a body 12 and first and second terminals 16a, 16b. FIG. 1B shows a side view of the SMD 10 of FIG. 1A, and FIG. 1C shows the SMD 10 of FIGS. 1A and 1B mounted on a mounting surface 24 of a circuit boards. More particularly, the SMD 10 is shown to be mounted so that the first and second terminals 16a, 16b are secured (e.g., by solder) to respective mounting pads 22a, 22b on the mounting surface 24 of the circuit board to provide electrical connections between the circuit board and one or more circuits and/or one or more electrical devices implemented within the body 12.

It is noted that some electrical devices are configured to include a body and two electrodes implemented on opposite sides of the body. Such electrical devices are commonly included in through-hole packaged devices having axial or radial leads. However, an electrical device having the foregoing opposing-electrodes configuration by itself is not suitable for surface-mounting applications.

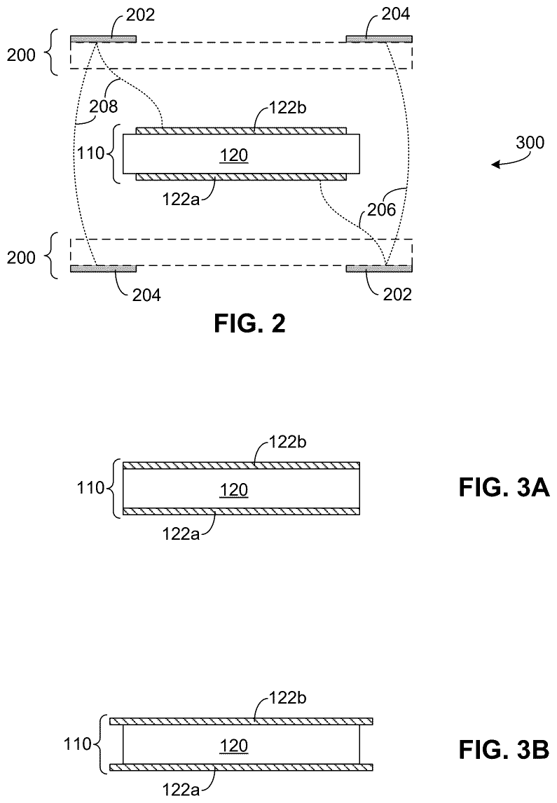

Disclosed herein are examples related to electrical devices with opposing-electrodes configuration packaged into surface mount devices (SMDs). FIG. 2 depicts a packaged device 300 that includes an electrical device 110 having first and second electrodes 122a, 122b implemented on opposite sides of a body 120. Examples of such an electrical device are provided herein.

In FIG. 2, the electrical device 110 is shown to be positioned between two terminal assemblies 200 such that the first electrode 122a is electrically connected to one of two terminals 202, 204 of each of the two terminal assemblies 200, and the second electrode 122b is electrically connected to the other terminals of the two terminal assemblies 200. More particularly, an electrical connection depicted as 206 is shown to electrically connect the first electrode 122a of the electrical device 110 to the terminal 202 of the lower (when in the orientation shown in FIG. 2) terminal assembly 200, and to the terminal 204 of the upper terminal assembly 200. Similarly, an electrical connection depicted as 208 is shown to electrically connect the second electrode 122b of the electrical device 110 to the terminal 202 of the upper terminal assembly 200, and to the terminal 204 of the lower terminal assembly 200. Examples related to the terminal assemblies 200 are described herein in greater detail.

In the example of FIG. 2, each of the two electrodes 122a, 122b of the electrical device 120 is shown to have a lateral dimension that is less than the corresponding lateral dimension of the body 120. However, it will be understood that an electrical device utilized to form a packaged device having one or more features as described herein can have electrodes having different dimensions relative to its corresponding body.

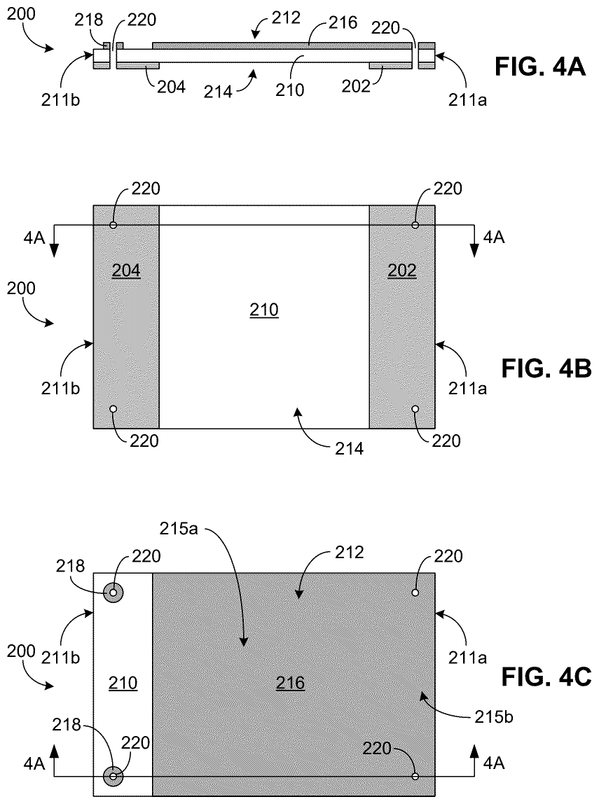

For example, FIG. 3A shows that in some embodiments, an electrical device 110 that can be utilized for a packaged device as described herein can include electrodes 122a, 122b with each electrode having a lateral dimension that is approximately the same as the corresponding lateral dimension of the body 120.

In another example, FIG. 3B shows that in some embodiments, an electrical device 110 that can be utilized for a packaged device as described herein can include electrodes 122a, 122b with each electrode having a lateral dimension that is greater than the corresponding lateral dimension of the body 120.

In some embodiments, an electrical device that can be utilized for a packaged device as described herein can include electrodes with lateral dimensions that are in any combination of the examples of FIGS. 2, 3A and 3B.

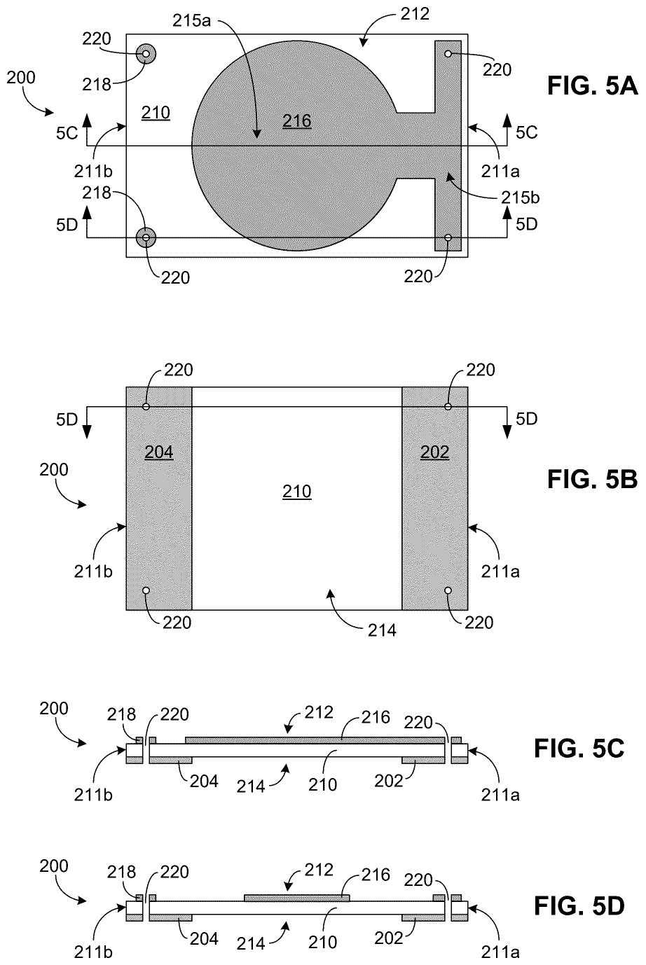

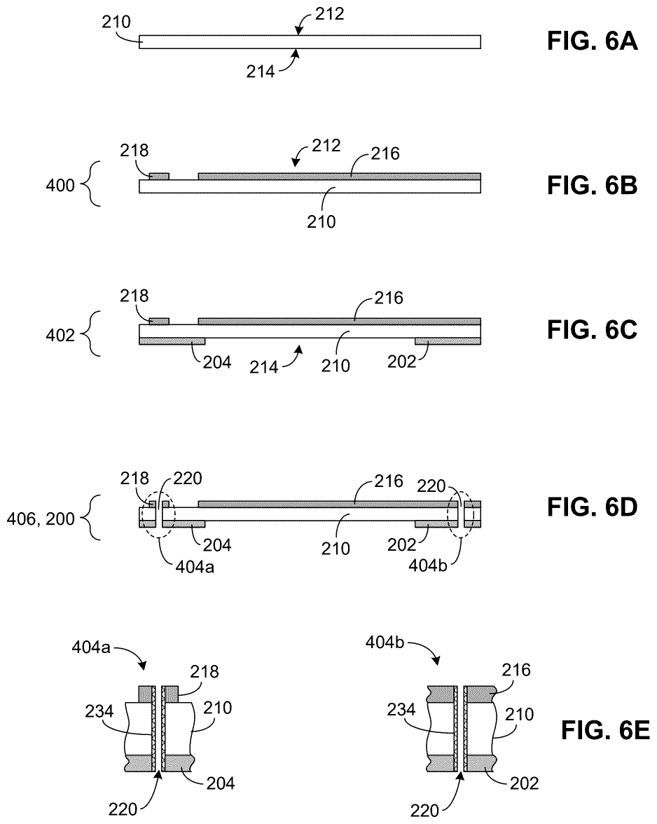

FIGS. 4 and 5 show two non-limiting examples of terminal assemblies that can be utilized to form a packaged device as described herein. In a first example, FIG. 4A shows a side sectional view of a terminal assembly 200 along the section indicated on each of plan views of FIGS. 4B and 4C. The plan view of FIG. 4B shows an outer side of the terminal assembly 200, and the plan view of FIG. 4C shows an inner side of the terminal assembly 200.

In a second example, FIG. 5A shows a plan view of an inner side of a terminal assembly 200, and FIG. 5B shows a plan view of an outer side of the terminal assembly 200. FIG. 5C shows a side sectional view of the terminal assembly 200 along the section indicated on the plan view of FIG. 5A. FIG. 5D shows a side sectional view of the terminal assembly 200 along the section indicated on each of the plan views of FIGS. 5A and 5B.

Referring to FIGS. 4 and 5, it will be understood that a feature associated with a terminal assembly can be applicable to either or both of the terminal assembly 200 of FIG. 4 and the terminal assembly 200 of FIG. 5. Thus, for the purpose of description, it will be understood that unless indicated otherwise, a given feature is included in each of the terminal assembly 200 of FIG. 4 and the terminal assembly 200 of FIG. 5.

FIGS. 4 and 5 show that in some embodiments, a substrate 210 of the terminal assembly 200 can include one or more layers of a printed circuit board (PCB) material. Such a substrate is shown to include an inner side 212 that will face an electrical device (when assembled), and an outer side 214 where terminals 202, 204 are implemented. The substrate 210 is also shown to include an edge 211a on which lateral side (or near thereto) where the terminal 202 is implemented on the outer side 214, and an edge 211b on which lateral side (or near thereto) where the terminal 204 is implemented on the outer side 214.

In some embodiments, the terminals 202, 204 of FIGS. 4 and 5 can be formed from conductive material such as metal and be dimensioned to allow surface mounting of a packaged device having the terminal assembly 200.

Referring to FIGS. 4A, 4C, 5A, 5C and 5D, the terminal assembly 200 can further include a conductive feature 216 formed on the inner side 212 of the respective substrate 210. Such a conductive feature can be formed from, for example, patterned copper foil.

Although various examples are described herein in the context of such a PCB substrate, it will be understood that the terminal assembly 200 can utilize other forms of substrate.

For example, an insulator substrate such as a ceramic substrate (e.g., alumina) providing higher temperature capabilities than PCB materials can be utilized as the substrate 210 of FIGS. 4 and 5. On such a substrate, one or more conductive features can be formed with printed thick film conductor materials, or be formed by deposition (e.g., evaporation or sputtering) of conductive metal followed by patterned removal by an etching process. Optionally, thick film insulator material can be deposited over the thick film conductor material to form pad area(s) that generally align with the electrode(s) of an electrical device being packaged. Formation of a plurality of such pad areas can be utilized to accommodate an electrical device having a plurality of electrodes on the respective one of its sides.

In another example, the substrate 210 of FIGS. 4 and 5 can be implemented to include a metal such as steel to provide higher thermal conductivity capabilities than PCB materials. On such a metal, an insulative material such as glass or polymer can be deposited, including inside the holes through which the conductor pins or wires are to be installed, thereby insulating the conductor pins or wires from the metal. On the insulative material, one or more conductive features can be formed with thick film conductor ink printed and fired, or be formed by deposition (e.g., evaporation or sputtering) of metal followed by patterned removal of the deposited metal. Optionally, thick film insulator material can be deposited over the thick film conductor material to form pad area(s) that generally align with the electrode(s) of an electrical device being packaged. Formation of a plurality of such pad areas can be utilized to accommodate an electrical device having a plurality of electrodes on the respective one of its sides.

In the first example of FIG. 4C, the conductive feature 216 is shown to have a rectangular shape dimensioned to include an electrode-contact portion 215a that overlap with some or all of an electrode (e.g., 122a or 122b in FIG. 2) of an electrical device (110 in FIG. 2) when the electrical device 110 is coupled with the terminal assembly 200. The rectangular shaped conductive feature 216 is also shown to include an edge portion 215b implemented at or near an edge 211a on the inner side 212 of the substrate 210 and electrically connected to the electrode-contact portion 215a, such that the edge portion 215b overlaps at least partially with the terminal 202 (FIGS. 4A and 4B), on opposite sides of the substrate 210, so as to allow formation of an electrical connection therebetween as described herein.

In the second example of FIG. 5A, the conductive feature 216 is shown to have a shape dimensioned to promote desired positioning of an electrode (e.g., 122a or 122b in FIG. 2) of an electrical device (110 in FIG. 2) when the electrical device 110 is coupled with the terminal assembly 200. For example, and assuming that the electrode (e.g., 122a or 122b in FIG. 2) has a circular shape (in a plan view), the conductive feature 216 can include a circular shaped electrode-contact portion 215a dimensioned appropriately with respect to the dimension of the circular-shaped electrode. Accordingly, when the electrical device is coupled with the terminal assembly 200 (e.g., by a solder reflow operation), the circular-shaped electrode of the electrical device is more likely to be centered with respect to the circular shaped electrode-contact portion 215a of the conductive feature 216 of the terminal assembly 200.

In the example of FIG. 5A, the conductive feature 216 is shown to further include an edge portion 215b implemented at or near an edge 211a on the inner side 212 of the substrate 210 and electrically connected to the circular shaped electrode-contact portion 215a. Similar to the example of FIG. 4C, the edge portion 215b of the conductive feature 216 of FIG. 5A is shown to overlap at least partially with the terminal 202 (FIGS. 5C and 5D), on opposite sides of the substrate 210, so as to allow formation of an electrical connection therebetween as described herein.

It will be understood that a conductive feature for providing an electrical connection between one electrode of an electrical device to a terminal on the other side of a substrate can have shapes that are different than the examples shown in FIGS. 4 and 5. In some embodiments, such a conductive feature formed on an inner side of a substrate of a terminal assembly can include an electrode-contact portion having any shape dimensioned to provide an electrical contact with the electrode, and an edge portion having any shape and electrically connected to the electrode-contact portion. Such an edge portion can be implemented on the inner side of the substrate of the terminal assembly at or near an edge, so as to allow formation of an electrical connection between the edge portion and a corresponding terminal on the outer side of the substrate. As described herein, such an edge portion and corresponding terminal can overlap at least partially on opposite sides of the substrate, and the electrical connection therebetween can be provided by one or more conductive through-substrate structures.

Referring to FIGS. 4 and 5, and as described above, the terminal 202 on the outer side 214 of the substrate 210 is electrically connectable to the conductive feature 216 on the inner side 212 of the substrate 210. Thus, when an electrical device is positioned on such a terminal assembly, the respective electrode of the electrical device is connectable to the corresponding terminal 202 through the conductive feature 216.

In some embodiments, the foregoing electrical connectivity between the conductive feature 216 on the inner side 212 of the substrate 210 and the respective terminal 202 on the outer side 214 of the substrate 210 can be provided by a conductive structure that extends through one or more through-substrate holes 220. In the examples of FIGS. 4 and 5, two of such through-substrate holes are shown to be implemented, such that each through-substrate hole 220 is positioned near a respective corner near the edge (211a) side of the rectangular shaped substrate 210. It will be understood that other numbers of such through-substrate holes can also be utilized. Additional examples related to such through-substrate holes are described herein in greater detail.

In some embodiments, the foregoing conductive structure that extends through a respective through-substrate hole 220 (in an assembled packaged device) can be a conductive pin. Such a conductive pin can be configured to provide electrical connectivity, as well as at least some mechanical support for the assembled packaged device at the respective through-substrate hole 220. Additional examples related to such conductive pins are described herein in greater detail.

Referring to the examples of FIGS. 4 and 5, one can see that the inner side 212 of the substrate 210 is configured so that the conductive feature 216 is electrically isolated from the surface near the edge 211b that is opposite from the edge 211a. More particularly, the conductive feature 216 can be configured so that when it engages an electrode of an electrical device, there is an area on the inner side 212 of the substrate near the edge 211b that is electrically isolated from the electrode and the conductive feature 216.

In the example of FIG. 4C, the rectangular shaped conductive feature 216 can be dimensioned to provide the electrode-contact portion 215a and have an edge away from the edge 211b of the substrate 210 to provide a rectangular-shaped area of the inner side 212 that is electrically isolated from the conductive feature 216. It is noted that when such a conductive feature engages an electrode of an electrical device, the electrode may or may not be completely within the boundary of the conductive feature 216. If the electrode extends laterally beyond the edge (left side in FIG. 4C) of the conductive feature 216, the electrode can still be electrically isolated from through-substrate holes 220 positioned near the edge 211b that are utilized to electrically connect the other electrode of the electrical device to the other terminal 204 as described herein.

In the example of FIG. 5A, the circular shaped electrode-contact portion 215a of the conductive feature 216 can be dimensioned to provide the electrode-centering functionality provide an area of the inner side 212 near the edge 211b that is electrically isolated from the electrode-contact portion 215a. It is noted that when such an electrode-contact portion engages an electrode of an electrical device, the electrode may or may not be completely within the boundary of the electrode-contact portion 215a. If the electrode extends laterally beyond such a boundary (e.g., left side in FIG. 5A) of the of the electrode-contact portion 215a, the electrode can still be electrically isolated from through-substrate holes 220 positioned near the edge 211b that are utilized to electrically connect the other electrode of the electrical device to the other terminal 204 as described herein.

Based on the foregoing examples of FIGS. 4 and 5, one can see that two of the same or similar terminal assemblies 200 can be utilized with an electrical device therebetween to provide electrical connections between the electrodes of the electrical device and their respective terminals of the terminal assemblies. More particularly, a first one of the terminal assemblies can be oriented as shown in FIGS. 4 and 5 (e.g., where the edge portion 215b is of the conductive feature 216 is on the right side as in FIGS. 4C and 5A), and the other terminal assembly is oriented to be rotated 180 degrees with respect to the orientation of the first terminal assembly (such that the edge portion 215b of the second terminal assembly is on the left side).

Configured in the foregoing manner, the first electrode of the electrical device can be electrically connected to the electrode-contact portion of the second conductive feature 216, and thus to the corresponding terminal of the first terminal assembly through respective conductive pins. Similarly, the second electrode of the electrical device can be electrically connected to the electrode-contact portion of the second conductive feature 216, and thus to the corresponding terminal of the second terminal assembly through respective conductive pins.

In some embodiments, the conductive pins that provide the electrical connection between the conductive feature 216 of the first terminal assembly can be utilized to also provide an electrical connection to the other terminal of the second terminal assembly through the respective through-substrate holes 220 (near the other edge 211b in FIGS. 4C and 5C). Similarly, the conductive pins that provide the electrical connection between the conductive feature 216 of the second terminal assembly can be utilized to also provide an electrical connection to the other terminal of the first terminal assembly through the respective through-substrate holes 220.

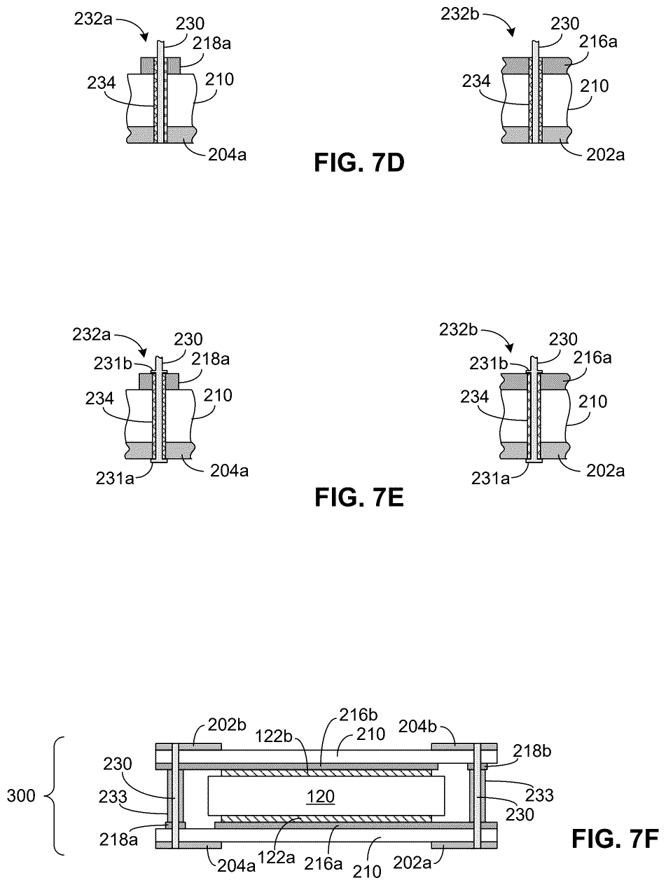

Examples related to the foregoing configuration utilizing two same or similar terminal assemblies are described herein in reference to FIGS. 7A to 7E. In such example, the two terminal assemblies are assumed to be the same, other than being rotated 180 degrees with respect to each other. However, it will be understood that in some embodiments, two terminal assemblies utilized in a packaged device as described herein may or may not be the same. For example, a first terminal assembly may be similar to the example of FIG. 4, and a second terminal assembly may be similar to the example of FIG. 5. It will also be understood that either or both of two terminal assemblies can have different configurations (e.g., different shapes of conductive features) from the examples of FIGS. 4 and 5.

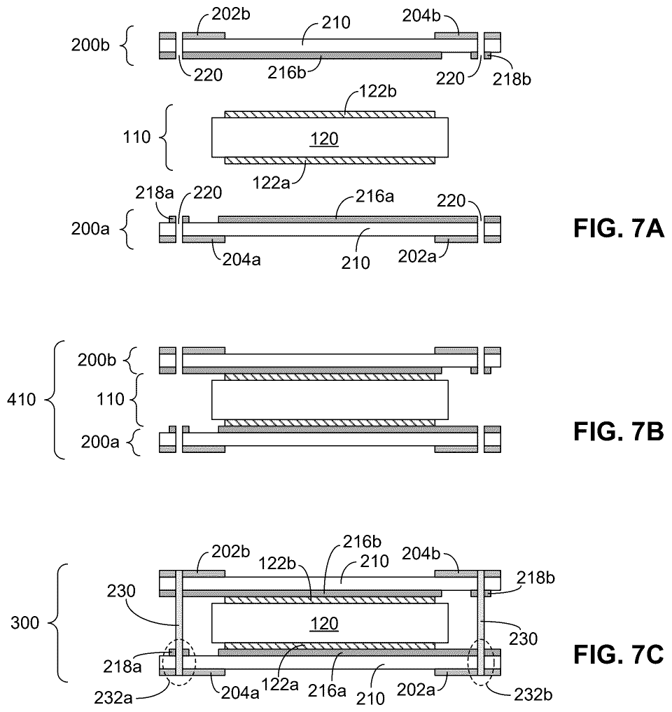

FIGS. 6A to 6D show an example process for fabricating a terminal assembly, such as the terminal assembly 200 of FIG. 4. It will be understood that a similar process can also be utilized to fabricate the terminal assembly 200 of FIG. 5, or any other similar terminal assemblies.

Referring to FIG. 6A, a substrate 210 having first and second sides can be formed or provided. The first side can be an inner side 212, and the second side can be an outer side 214 of the substrate 210. In some embodiments, the substrate can include one or more layers of printed circuit board (PCB) material.

In FIG. 6B, a conductive feature 216 can be formed on the inner side 212 of the substrate 210 to yield an assembly 400. As described herein, such a conductive feature can be dimensioned to allow contacting with an electrode of an electrical device and to facilitate further electrical connection through the substrate 210. In some embodiments, the conductive feature 210 can be formed by a patterned conductive foil such as a copper foil.

In some embodiments, a pattern of conductive foil 218 such as copper foil can be provided on the inner side 212 in an area where each of through-substrate holes are to be formed near the edge (211b in FIG. 4C) opposite from the edge portion of the conductive feature 216. As described herein, such a pattern of conductive foil can facilitate mechanical and electrical connection of a conductive pin extending through a through-substrate hole associated with the pattern of conductive foil.

In FIG. 6C, first and second terminals 202, 204 can be formed on the outer side 214 of the substrate 210 to yield an assembly 402. In some embodiments, such terminals can be configured as described herein.

In FIG. 6D, through-substrate holes 220 are shown to be formed to yield an assembly 406. The assembly 406 is substantially same as the terminal assembly 200 of FIG. 4; thus, the assembly 406 is also indicated as 200.

FIG. 6E shows an enlarged view of regions 404a, 404b about through-substrate holes 202 on opposite ends of the substrate 210. Referring to FIGS. 6D and 6E, each through-substrate hole 220 can be formed by, for example, drilling through the corresponding conductive foil (218 or 216), the substrate 210, and the corresponding terminal (204 or 202). In some embodiments, such drilled holes can be plated to form a conductive wall 234 that provides an electrical connection between the two conductors on the opposite sides of the substrate even in the absence of a pin therethrough.

As described herein, two terminal assemblies that are substantially the same can be utilized with an electrical device having electrodes suitable for axial or radial leads, to form a packaged device having a surface mounting configuration. FIGS. 7A to 7C show an example process that can be utilized to form a packaged device with the foregoing parts.

FIG. 7A shows an unassembled view of an electrical device 110 and first and second terminal assemblies 200a, 200b. The electrical device 110 is shown to include first and second electrodes 122a, 122b implemented on opposite sides of a body 120, similar to the examples of FIGS. 2 and 3. The first terminal assembly 200a is shown to be positioned and oriented so that its conductive feature 216a will engage the first electrode 122a of the electrical device 110, and the second terminal assembly 200b is shown to be positioned and oriented so that its conductive feature 216b will engage the second electrode 122b of the electrical device 110.

FIG. 7B shows an assembled view of the parts shown in FIG. 7A. More particularly, the first electrode (122a in FIG. 7A) is shown to engage the conductive feature (216a in FIG. 7A) of the electrical device 110, and the second electrode 122b is shown to engage the conductive feature 216b of the electrical device, so as to form an assembly 410. In some embodiments, such engagements between the electrodes and the respective conductive features can be formed by, for example, a soldering process.

FIG. 7C shows an assembly resulting from placing of a conductive pin 230 through each through-substrate hole (220 in FIG. 7A) of the first terminal assembly 200a and the corresponding through-substrate hole of the second terminal assembly 200b. In the context of the examples of FIGS. 4 and 5, each terminal assembly includes four through-substrate holes positioned near the four corners. Thus, in the example of FIG. 7C, four of such conductive pins 230 can be utilized to provide respective electrical connections and mechanical support for the assembly. In FIG. 7C, such an assembly is an example embodiment of the packaged device 300 of FIG. 2; thus, the assembly of FIG. 7C is also indicated as 300.

In some embodiments, each conductive pin 230 of FIG. 7C can be an appropriately dimensioned pin or wire preferably having a thermal stress relief feature. Such a pin or wire can be inserted into respective through-substrate holes of the two terminal assemblies of an assembly such as the assembly 410 of FIG. 7B. Once inserted through the respective holes, the pin or wire can be attached mechanically and electrically to conductive structure(s) associated with each of the two terminal assemblies by, for example, swaging, brazing or soldering.

In the example of FIG. 7C, portions of the left and right conductive pins 230 and their engagements with the respective holes of the first terminal assembly are indicated as 232a and 232b, respectively. FIG. 7D shows an enlarged view of such portions, where the pins or wires 230 are not swaged, but inserted through the respective holes with conductive walls 234. Such inserted pins or wires can be secured to the terminal assembly by, for example, brazing or soldering. It will be understood that an end of each pin or wire may be generally flush with the surface of the terminal (216 or 218), protrude slightly beyond or be recessed from such a surface.

Similarly, FIG. 7E shows an enlarged view of the portions 232a, 232b indicated in FIG. 7C. In the example of FIG. 7E, each pin or wire 230 can be swaged to provide either or both of shoulder structures 231a, 231b of the pin or wire at respective surface(s) of the terminal assembly.

Referring to FIGS. 7A to 7E, one can see that in the packaged device 300 of FIG. 7C, the first electrode 122a of the electrical device 110 is electrically connected to the right terminal 202a of the lower terminal assembly 200a, and to the right terminal 204b of the upper terminal assembly 200b, through the conductive feature 216a and the conductive pins 230 (on the right side). Similarly, the second electrode 122b of the electrical device 110 is electrically connected to the left terminal 204a of the lower terminal assembly 200a, and to the left terminal 202b of the upper terminal assembly 200b, through the conductive feature 216b and the conductive pins 230 (on the left side). As described herein, such electrical connectivity and mechanical support for the packaged device 300 can be provided by use of two terminal assemblies that are substantially the same with one being rotated (with respect to a center axis normal to the plane of one terminal assembly) about 180 degrees, and a plurality of conductive pins or wires.

FIG. 7F shows that in some embodiments, a packaged device 300 having one or more features as described herein can include an insulator sleeve 233 implemented to cover each conductive pin or wire 230 between the two terminal assemblies. Such an insulator sleeve can be configured to provide functionalities such as reduction and/or mitigation of thermal expansion mismatch of parts associated with the pin or wire, better handling of high voltage operating conditions (if configured as such), or some combination thereof. In the example of FIG. 7F, the remaining parts of the packaged device 300 can be substantially the same as the example of FIG. 7C.

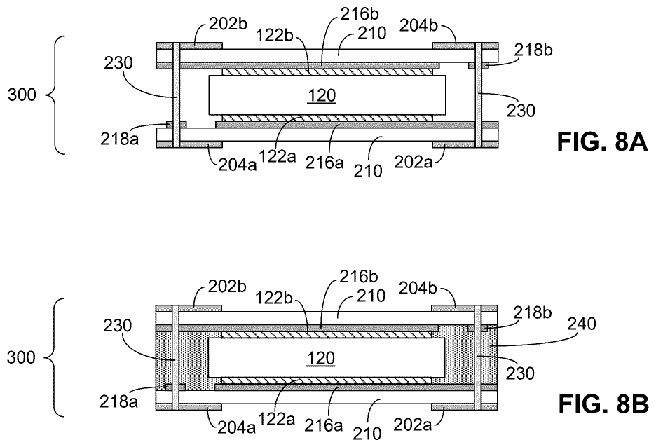

FIG. 8A shows that in some embodiments, a packaged device 300 which is similar to the example of FIG. 7C can include an open space on the periphery of the electrical device sandwiched between two terminal assemblies. FIG. 8B shows that in some embodiments, some or all of such a space can be optionally filled with an electrical insulator material such as an epoxy or elastic material, a high temperature silicone sealer, or some combination thereof. In some embodiments, such a filler material can be provided to substantially cover the periphery of the electrical device, as well as each of the conductive pins or wires.

In some embodiments, terminal assemblies having one or more features as described herein can be fabricated in an array format. Such an array format can be singulated to provide a plurality of individual terminal assemblies, or be further utilized to fabricate a plurality of packaged devices in an array format.

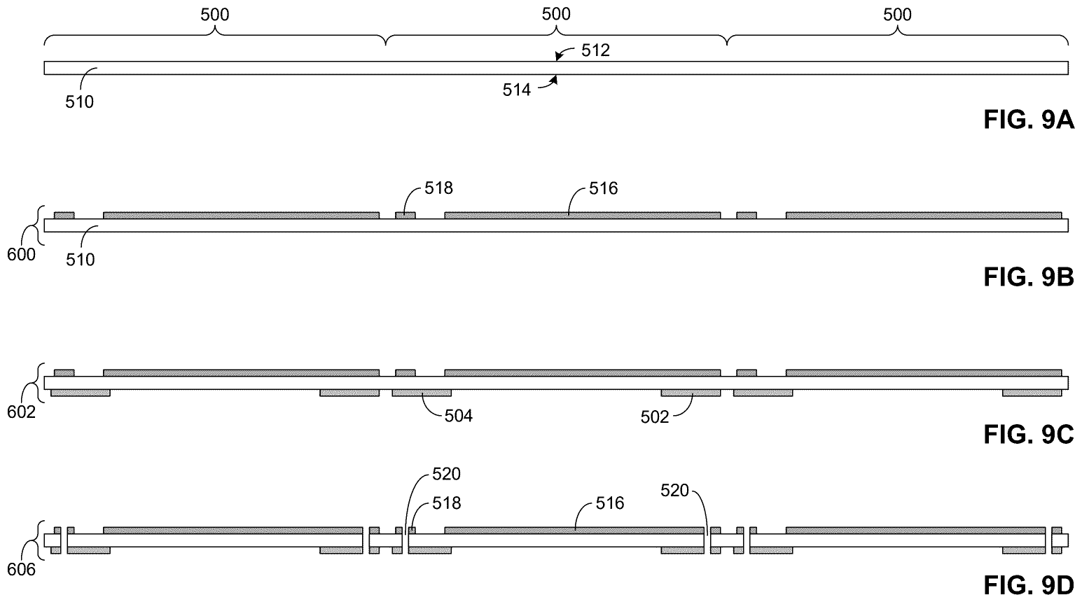

FIGS. 9A to 9D show an example process that can be utilized to fabricate an array of terminal assemblies. FIG. 9A shows that in some embodiments, a substrate panel 510 having opposing sides 512, 514 (e.g., inner side 512, outer side 514) can be provided or formed. Such a panel can include one or more layers of a printed circuit board (PCB) material similar to the substrate 210 of FIGS. 4 to 6.

In the example of FIG. 9A, the panel 510 is shown to include a plurality of units generally indicated as 500. Each of such units can eventually become a terminal assembly having one or more features as described herein.

FIG. 9B shows that in some embodiments, a conductive feature 516 and an isolated conductor 518 can be formed for each unit on the inner side 512 of the panel to yield an assembly 600. In some embodiments, such conductive features (516) and isolated conductors (518) can be formed in manners similar to the examples of FIGS. 4 to 6.

FIG. 9C shows that in some embodiments, terminals 502, 504 can be formed for each unit on the outer side 514 of the panel to yield an assembly 602. In some embodiments, such terminals can be formed in manners similar to the examples of FIGS. 4 to 6.

It will be understood that the formation of conductive features of FIG. 9B may be performed prior to, after, or generally concurrently with the formation of terminals of FIG. 9C.

FIG. 9D shows that in some embodiments, through-substrate holes 520 can be formed for each unit (500 in FIG. 9A) to yield an assembly 606. In some embodiments, such holes can be formed and configured in manners similar to the examples of FIGS. 4 to 6.

As described herein, the assembly 606 of FIG. 9D can be singulated to provide a plurality of individual terminal assemblies; and two of such terminal assemblies can be utilized to form a packaged device similar to the examples of FIGS. 7 and 8.

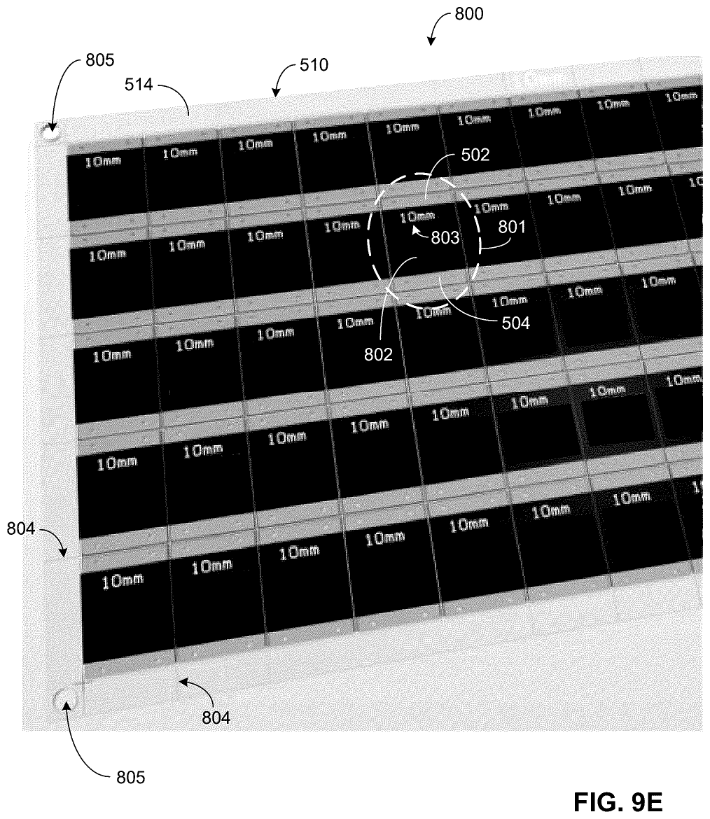

In some embodiments, the assembly 606 of FIG. 9D can be further utilized to fabricate a plurality of packaged devices in an array format. FIGS. 10 to 13 show various examples related to such an array-format fabrication process.

FIGS. 9E to 9H show examples related to an assembly 800 that includes an array of fabricated units 801 similar to the array of fabricated units of the assembly 606 of FIG. 9D. More particularly, FIG. 9E shows a portion of an outer side 514 of a panel 510 of the assembly 800, such that the terminal side of each unit 801 is shown to include two terminals 502, 504. FIG. 9E also shows that in some embodiments, an insulator layer 802 such as a solder mask can be optionally provided on the terminal side of each unit 801. Such a solder mask can be configured to provide insulation region(s) between two or more terminals, to provide a surface suitable for marking (e.g., part information 803), or some combination thereof.

FIG. 9F shows a plan view of the assembly 800 of FIG. 9E, but without the insulator layer (802 in FIG. 9E). FIG. 9G shows a plan view of an inner side 512 of the panel 510 of the assembly 800 of FIG. 9F. FIG. 9H shows a sectional view of an example score line that can be provided on the panel 510 to facilitate singulation of the fabricated units 801.

Referring to FIGS. 9E to 9G, it is noted that in some embodiments, the panel 510 can include a plurality of indexing features 805 such as indexing holes provided at selected locations of the panel 510. For example, each corner of the panel 510 can be provided with an indexing hole 805, and such holes (805a, 805b, 805c, 805d in FIGS. 9F and 9G) can be dimensioned and positioned to allow accurate alignment of a pair of units 801 during a process when two assemblies 800 sandwich an array of electrical devices therebetween. It is noted that in some embodiments, such two assemblies (800) can be identical assemblies with the panel 510 of each assembly 800 including edges 811, 812, 813, 814. For such a pair of identical assemblies, the foregoing sandwich configuration can be achieved by rotating one panel 180 degrees with respect to the other when the inner sides 512 of the two panels face each other. For example, one panel can be rotated 180 degrees with respect to the other panel so that both edges 812 of the panels are aligned, both edges 814 are aligned, edge 811 of the panel is aligned with edge 813 of the panel, and edge 813 of the panel is aligned with edge 811 of the other panel, when the inner sides 512 of the two panels face each other.

FIGS. 9E to 9H show that in some embodiments, an assembly 800 having an array of units 801 formed on a panel 510 can be configured to facilitate singulation of the units 801. It will be understood that such singulation can be achieved to provide a plurality of units that can be utilized to fabricate a packaged device as described herein. Singulation can also be achieved after an array of packaged devices are produced while in an array format where two assemblies 800 sandwich an array of electrical devices.

In some embodiments, the foregoing singulation-facilitating feature can include a grid of score lines 804 arranged so that each rectangle of the grid generally defines the boundary of the respective unit 801. FIG. 9H shows that in some embodiments, a score line 804 can be implemented to provide a groove having a sectional shape such as a V shape. In FIG. 9H, such a V-shaped groove is shown to be provided on both of the outer side 514 (as 804) and inner side 512 (as 804′) of the panel 510. In some embodiments, such a shaped groove can be implemented on one side of a panel 510 but not on the other side.

With the foregoing shaped grooves 804, 804′, the panel 510 is shown to have a reduced thickness region 822 where a clean singulation is likely to occur during a singulation process.

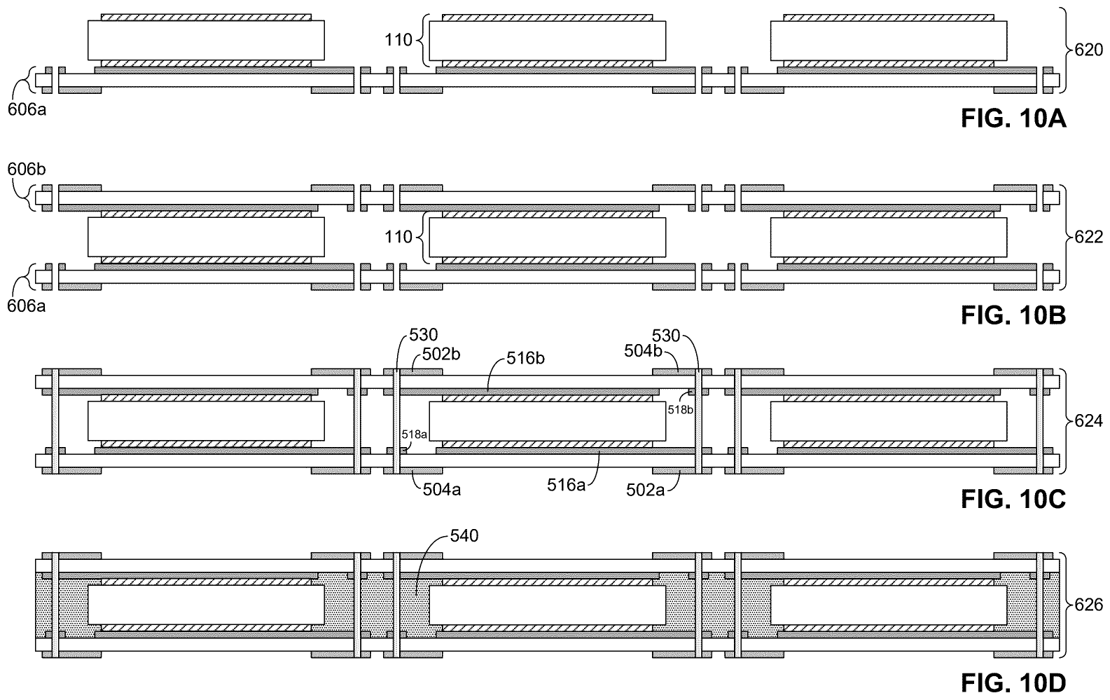

Referring to the example of FIG. 9H, it is noted that the shaped groove 804 (e.g., V shape) provides a surface 820; similarly, the shaped groove 804′ provides a surface 820′. Such surfaces, along with a newly created edge surface will be present at the respective edge of the unit upon singulation. Thus, a packaged device utilizing such units can include some or all of such surfaces at some or all of the edge portions of the packaged device. An example of such an edge configuration of a packaged device is described herein in reference to FIG. 13C.

FIG. 10A shows that in some embodiments, an electrical device 110 can be positioned on each unit of a first assembly 606a such as the assembly 606 of FIG. 9D, to yield an assembly 620.

In FIG. 10B, a second assembly 606b is shown to be positioned over the array of electrical devices 110, so as to yield an assembly 622. It is noted that in the example of FIG. 10B, the first and second assemblies 606a, 606b are oriented with respect to each other such that for each unit, the two terminal assemblies are oriented to be 180 degrees with respect to each other, similar to the examples of FIGS. 7 and 8. Accordingly, two substantially same terminal assemblies can be utilized to form a packaged device as described herein.

Referring to FIGS. 10A and 10B, it will be understood that in some embodiments, the electrical devices 110 can be secured mechanically and electrically to their respective units of the first assembly 606a (e.g., in manners similar to the examples of FIGS. 7A and 7B) first followed by similar securing of the second assembly 606b to the other side of the electrical devices 110. In some embodiments, both of the first and second assemblies 606a, 606b can be secured mechanically and electrically to the respective sides of the array of electrical devices 110 generally concurrently.

FIG. 10C shows that in some embodiments, conductive pins or wires (indicated as 530) can be inserted into respective through-substrate hole of each pair corresponding units of the first and second assemblies 606a, 606b, to yield an assembly 624. In some embodiments, such conductive pins or wires can be secured mechanically and electrically in manners similar to the examples of FIGS. 7C to 7F.

As described herein, a packaged device may or may not include an electrical insulator filler material between the two terminal assemblies to encapsulate the periphery of the sandwiched electrical device and the pins or wires between the terminal assemblies.

If such a filler material is to be provided, the assembly 624 of FIG. 10C can be further processed to introduce an electrical insulator filler material 540 while in the array format, to yield an assembly 626 of FIG. 10D. In some embodiments, material similar to the example of FIG. 8B can be introduced to fill substantially all of voids between the first and second assemblies 606a, 606b.

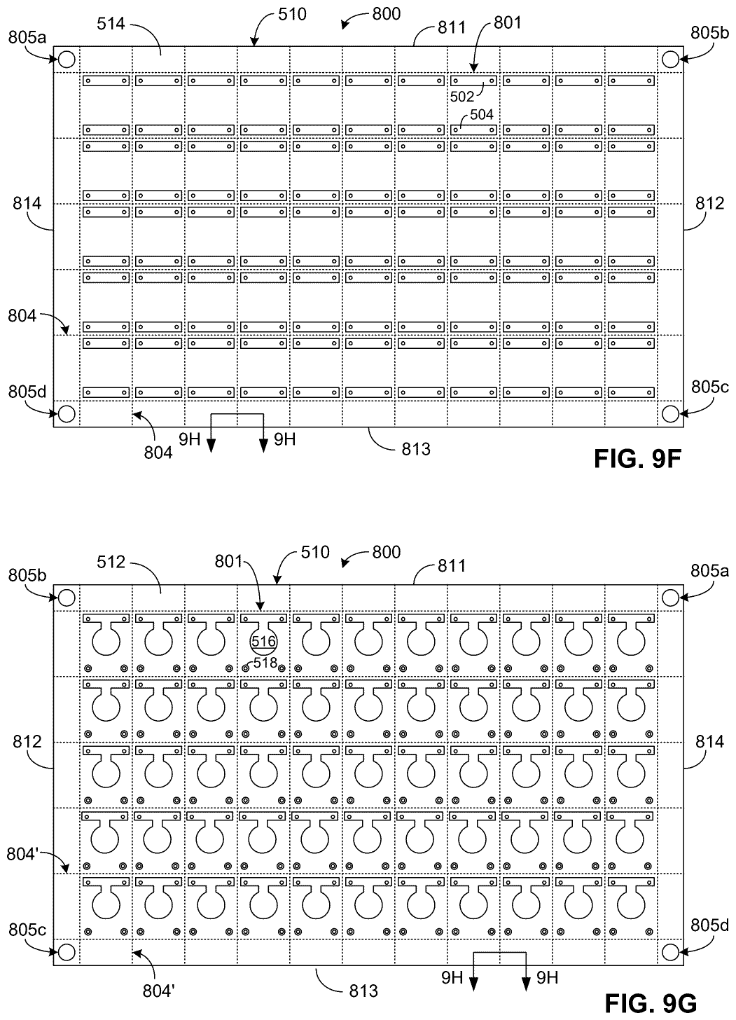

FIG. 11A shows an assembly 624 that is substantially the same as the assembly 624 of FIG. 10C (without electrical insulator filler). In the assembly 624 of FIG. 11A, each complete un-singulated units is indicated as 700. FIG. 11B shows that such an array of un-singulated units can be singulated utilizing, for example, sawing, cutting or the like, to yield a plurality of packaged devices 300 with each being similar to the packaged device 300 of FIG. 8A.

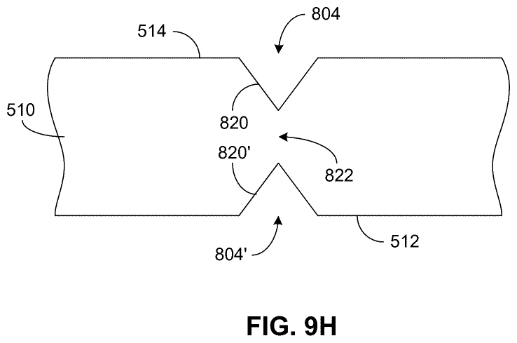

Similarly, FIG. 12A shows an assembly 626 that is substantially the same as the assembly 626 of FIG. 10D (with electrical insulator filler). In the assembly 626 of FIG. 12A, each complete un-singulated units is indicated as 700. FIG. 12B shows that such an array of un-singulated units can be singulated utilizing, for example, sawing, cutting or the like, to yield a plurality of packaged devices 300 with each being similar to the packaged device 300 of FIG. 8B.

Referring to FIGS. 11B and 12B, it is noted that the terminals (502a, 502b, 504a, 504b) on the outer side and the conductors (516a, 516b, 518a, 518b) on the inner side of respective substrates are dimensioned so that their lateral outside edges are laterally inward from the side walls of the substrates. In some embodiments, such laterally inward offset of each terminal or conductor can be dimensioned to accommodate the singulation process if sawing or cutting through the terminals/conductors is not desired.

It is also noted that in the examples of FIGS. 8A and 8B, the terminals (202a, 202b, 204a, 204b) on the outer side and the conductors (216a, 216b, 218a, 218b) on the inner side of respective substrates are dimensioned so that their lateral outside edges are generally flush with the side walls of the substrates.

Thus, it will be understood that a packaged device having one or more features as described herein can include a terminal implemented on an outer side of the substrate, where the terminal has a lateral outside edge that is either approximately flush with or laterally inward of the respective side wall of the corresponding substrate. Similarly, a conductor implemented on an inner side of a substrate can have a lateral outside edge that is either approximately flush with or laterally inward of the respective side wall of the corresponding substrate.

FIG. 13A shows a packaged device 300 as described herein, without an electrical insulator filler, and FIG. 13B shows a packaged device 300, also as described herein, with an electrical insulator filler. In each of such devices, an electrical device 110 is shown to be sandwiched between the two terminal assemblies to allow surface mounting of the device 300 even when the electrical device 110 itself is not suitably configured for such mounting.

FIG. 13C shows an edge configuration that can be implemented for a packaged device 300 such as the packaged device 300 of FIG. 13A or the packaged device 300 of FIG. 13B. In the example of FIG. 13C, two terminal assemblies are shown to provide respective edge portions, with each terminal assembly including an edge portion 830 of the respective substrate 510. Such an edge portion (830) is shown to include surfaces 820, 820′ associated with shaped grooves (804, 804′ in FIG. 9H), and an edge surface 832 resulting from singulation along the shaped grooves.

In the example of FIG. 13C, the space between the terminal assemblies is shown to be un-filled, similar to the example of FIG. 13A. It will be understood that in some embodiments, an edge configuration of FIG. 13C can also be implemented in a configuration where the space between the terminal assemblies is filled (similar to the example of FIG. 13B.

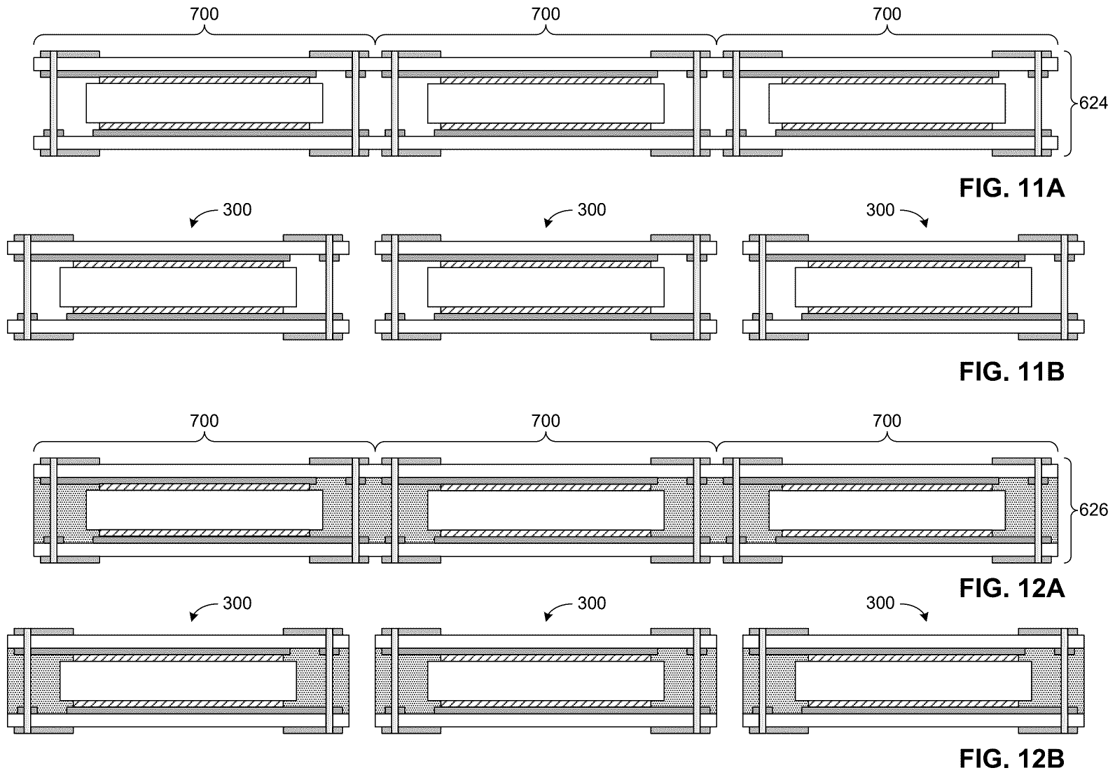

FIGS. 14A to 14D show non-limiting examples of electrical devices 110 that can be included in the packaged devices 300 of FIGS. 13A and 13B. For example, FIG. 14A shows an electrical device 110 implemented as a combination of a metal-oxide varistor (MOV), a gas discharge tube (GDT), and another MOV. Such an electrical device can include outer electrodes 122a, 122b that can engage the inner sides of two terminal assemblies to form a packaged device. Additional examples related to the electrical device 110 can be found in International Publication No. WO 2021/174140 which is expressly incorporated by reference in its entirely, and its disclosure is to be considered part of the specification of the present application.

In another example, FIG. 14B shows an electrical device 110 implemented as a combination of an MOV, a GDT, and another MOV. Such an electrical device can include outer electrodes 122a, 122b that can engage the inner sides of two terminal assemblies to form a packaged device. Additional examples related to the electrical device 110 can be found in International Publication No. WO 2020/047381 which is expressly incorporated by reference in its entirely, and its disclosure is to be considered part of the specification of the present application.

In yet another example, FIG. 14C shows an electrical device 110 implemented as a GDT. Such an electrical device can include electrodes 122a, 122b that can engage the inner sides of two terminal assemblies to form a packaged device. Additional examples related to the electrical device 110 can be found in International Publication No. WO 2020/257532 which is expressly incorporated by reference in its entirely, and its disclosure is to be considered part of the specification of the present application.

In yet another example, FIG. 14D shows an electrical device 110 implemented as a GDT. Such an electrical device can include electrodes 122a, 122b that can engage the inner sides of two terminal assemblies to form a packaged device. Additional examples related to the electrical device 110 can be found in International Publication No. WO 2018/222568 which is expressly incorporated by reference in its entirely, and its disclosure is to be considered part of the specification of the present application.

In yet more examples, an electrical device such as an MOV by itself, a transient-voltage-suppression (TVS) diode, or any other electrical component can include electrodes that can engage the inner sides of two terminal assemblies to form a packaged device.

As described herein, a terminal assembly can include a conductive feature implemented on one side of a substrate to allow an electrical contact to be made with an electrode of an electrical device. Also as described herein, such an electrical contact can be extended to a terminal implemented on the other side of the same substrate, as well as to a terminal of another terminal assembly, through a conductive pin or wire, where the other terminal assembly is oriented to be 180 degrees with respect to the terminal assembly.

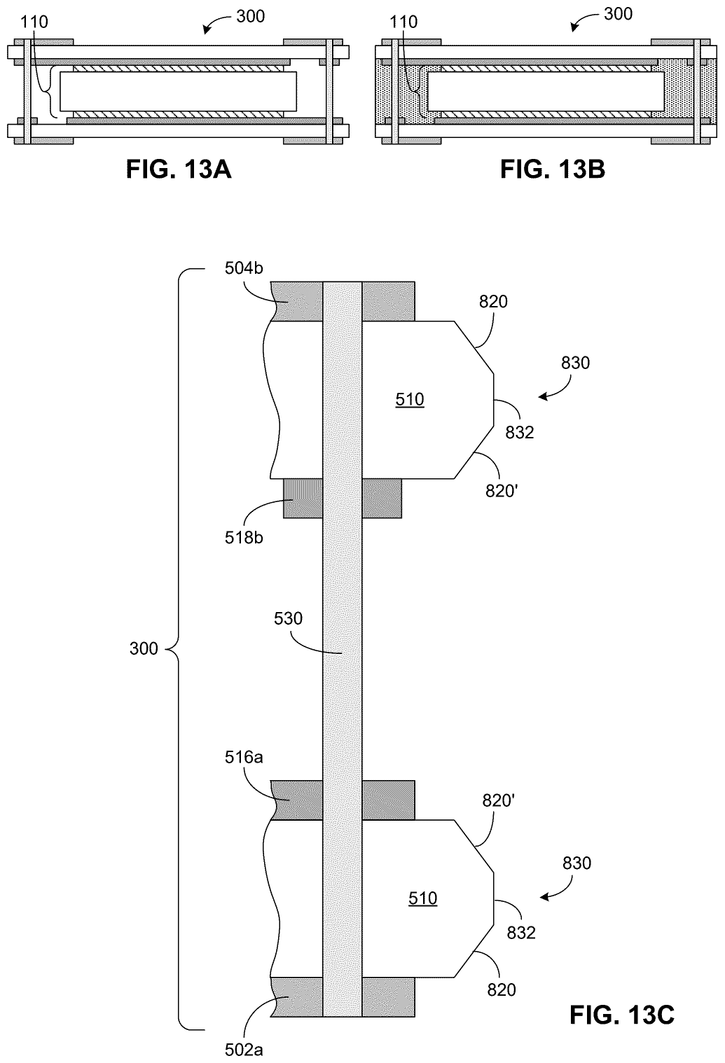

As described in reference to FIGS. 4 and 5, such a conductive feature can have different shapes. FIG. 15 shows another example shape of a conductive feature 216 that can be implemented on an inner side of a substrate 210 of a terminal assembly 200. In the example of FIG. 15, the conductive feature is shown to include a semi-circular boundary next to a rectangular shape. Thus, the semi-circular portion and a portion of the rectangular shape can be dimensioned to provide an electrode-contact portion 215a that overlap with some or all of an electrode of an electrical device when the electrical device coupled with the terminal assembly 200. The conductive feature 216 of FIG. 15 is also shown to include an edge portion 215b implemented at or near a respective edge of the substrate 210 and electrically connected to the electrode-contact portion 215a.

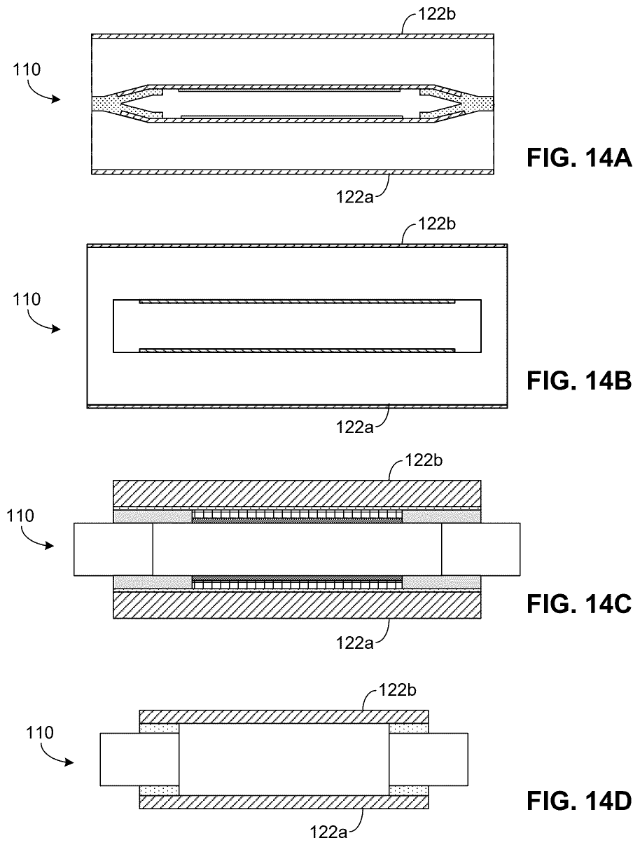

In various examples described herein in reference to FIGS. 2 to 15, it is assumed that an electrical device being sandwiched between two terminal assemblies has electrodes on two opposing sides of a body. In some applications, an electrical device may include more than one electrode on one side of a body. For example, FIG. 16 shows a side view of an electrical device 110 having a body with opposing sides. Two electrodes 122a, 122b are shown to be implemented on one side, and a third electrode 122c is shown to be implemented on the opposing side.

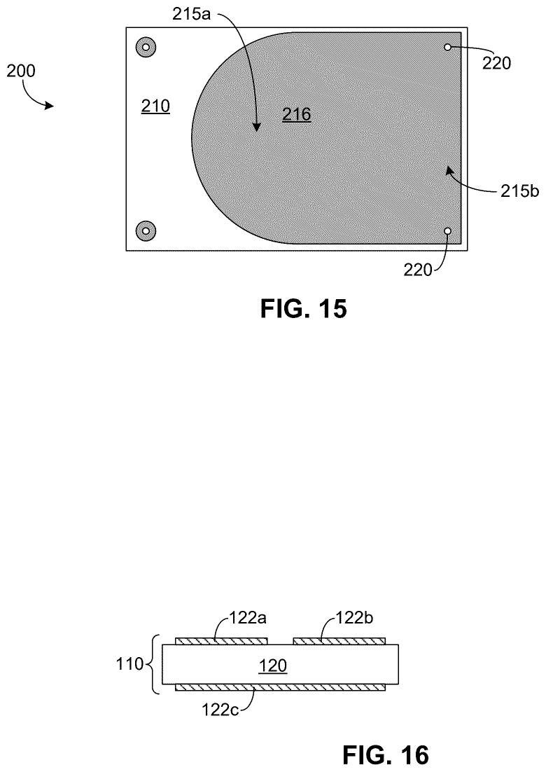

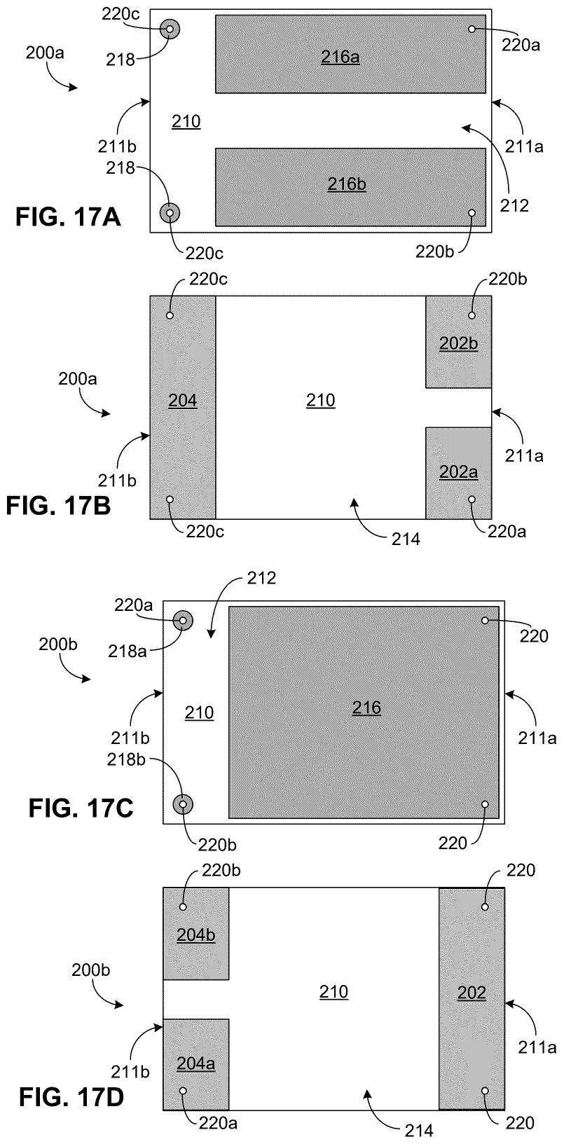

In some embodiments, terminal assemblies having one or more features as described herein can be configured to provide terminal-connecting functionalities that allows an electrical device having multiple electrodes (e.g., 110 of FIG. 16) to be configured as a surface-mount device. FIGS. 17 and 18 show various examples that can provide the foregoing packaging functionality.

FIGS. 17A to 17D show that in some embodiments, two terminal assemblies utilized to form a packaged device with an electrical device therebetween can have different conductive feature patterns. As described herein, such differently configured terminal assemblies can be utilized to accommodate an electrical device having more than one electrode on one of its sides, such as the example electrical device 110 of FIG. 16.

For example, FIG. 17A shows an inner side of a first terminal assembly 200a that can be utilized to provide contacts with the two electrodes 122a, 122b of the electrical device 110 of FIG. 16. More particularly, conductive features 216a, 216b that are electrically isolated from each other are shown to be implemented on an inner side 212 of a substrate 210. The substrate 210 is shown to include opposing edges 211a, 211b, such that each of the conductive features 216a, 216b includes an edge portion at or near the edge 211a.

In the example of FIG. 17A, each of the two conductive features 216a, 216b is shown to have a rectangular shape; however, it will be understood that other shapes can be utilized.

FIG. 17B shows an outer side of the first terminal assembly 200a of FIG. 17A. Two terminals 202a, 202b that are electrically isolated from each other are shown to be implemented at or near the edge 211a of the substrate 210, such that the terminal 202a at least partially overlaps with the conductive feature 216a on the other side, and the terminal 202b at least partially overlaps with the conductive feature 216b on the other side. Configured in the foregoing manner, the conductive feature 216a can be electrically connected to the terminal 202a through a hole 220a, and the conductive feature 216b can be electrically connected to the terminal 202b through a hole 220b.

Referring to FIGS. 17A and 17B, conductive patterns 218 implemented on the inner side 212 of the substrate 210 and electrically isolated from the conductive features 216a, 216b can be electrically connected to a terminal 204 implemented at or near the edge 211b and on the outer side of the substrate 210, through holes 220c.

FIG. 17C shows an inner side of a second terminal assembly 200b that can be utilized to provide contact with the electrodes 122c of the electrical device 110 of FIG. 16. More particularly, a conductive features 216 is shown to be implemented on an inner side 212 of a substrate 210. The substrate 210 is shown to include opposing edges 211a, 211b, such that the conductive feature 216 includes an edge portion at or near the edge 211a.

In the example of FIG. 17C, the conductive features 216 is shown to have a rectangular shape; however, it will be understood that other shapes can be utilized.

FIG. 17D shows an outer side of the second terminal assembly 200b of FIG. 17C. Two terminals 204a, 204b that are electrically isolated from each other are shown to be implemented at or near the edge 211b of the substrate 210, such that the terminal 204a is capable of being electrically connected to a conductive pattern 218a (on the inner side 212 of the substrate 210) through a hole 220a, and the terminal 204b is capable of being electrically connected to a conductive pattern 218b (on the inner side 212 of the substrate 210) through a hole 220b.

Referring to FIGS. 17C and 17D, the conductive feature 216 on the inner side 212 of the substrate 210 is shown to be capable of being electrically connected to a terminal 202 on the outer side 214 of the substrate through holes 220.

Configured in the foregoing manners, the first and second terminal assemblies 200a, 200b of FIGS. 17A to 17D can be utilized to form a packaged device with the electrical device 110 of FIG. 16 sandwiched therebetween. FIG. 18A shows such a packaged device from the edge 211a side of the first terminal assembly 200a, and FIG. 18B shows the same packaged device from the edge 211b side of the first terminal assembly 200a.

Referring to FIGS. 17 and 18, and more particularly to FIG. 18A, one can see that the electrode 122a of the electrical device is electrically connected to the terminal 202a of the first terminal assembly 200a through the conductive feature 216a (of the first terminal assembly 200a) and a conductive pin or wire 230a, and also to the terminal 204a of the second terminal assembly 200b through the conductive pin or wire 230a. Similarly, the electrode 122b of the electrical device is electrically connected to the terminal 202b of the first terminal assembly 200a through the conductive feature 216b (of the first terminal assembly 200a) and a conductive pin or wire 230b, and also to the terminal 204b of the second terminal assembly 200b through the conductive pin or wire 230b.

Referring to FIGS. 17 and 18, and more particularly to FIG. 18B, one can see that the single electrode 122c on the lower side of the electrical device is electrically connected to the terminal 202 of the second terminal assembly 200b through the conductive feature 216 (of the second terminal assembly 200b) and conductive pins or wires 230, and also to the terminal 204 of the first terminal assembly 200a through the conductive pins or wires 230.

Referring to the examples of FIGS. 17 and 18, it will be understood that each of the terminal assemblies 200a, 200b can be fabricated as described herein, individually or in an array. Similarly, the packaged device of FIGS. 18A and 18B can be fabricated individually or in an array, with or without a filler material.

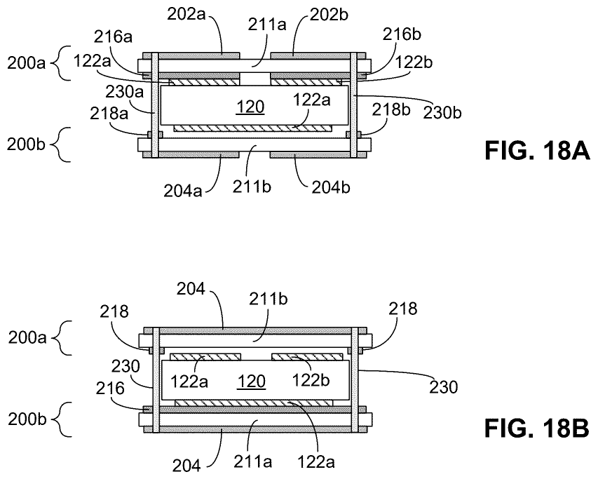

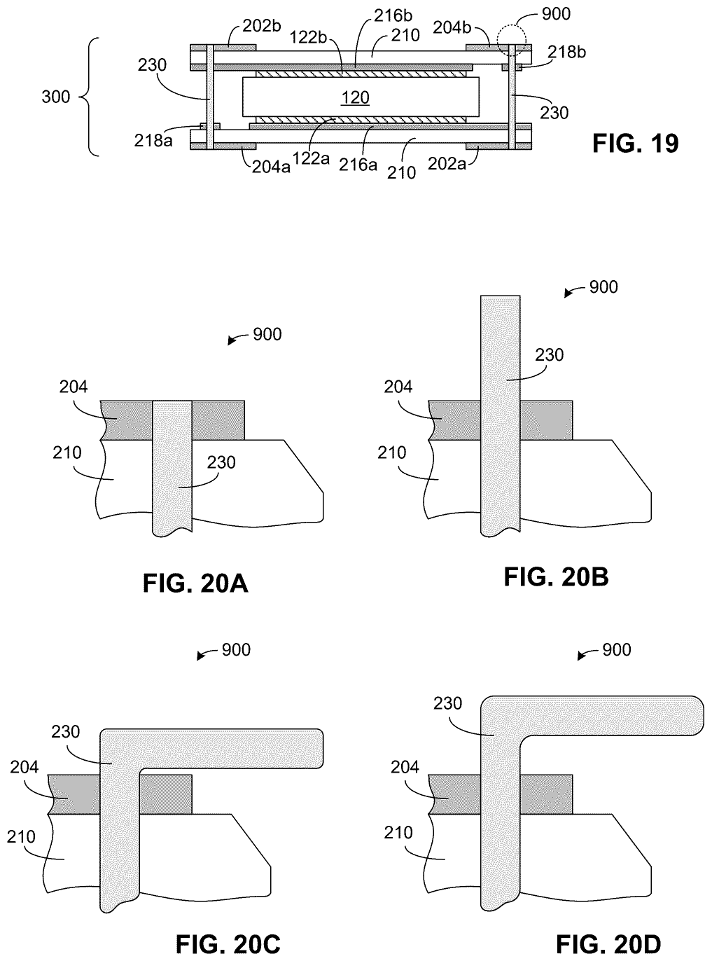

FIG. 19 shows a packaged device 300 having one or more features as described herein. Such a packaged device is shown to have an end configuration 900 for some or all of the conductive pins or wires 230. FIGS. 20A to 20D show non-limiting examples of the end configuration 900 of FIG. 19. While the packaged device 300 of FIG. 19 is depicted to be similar to the example of FIG. 8A, it will be understood that the end configuration 900 of FIG. 19 can also be implemented for other embodiments including the examples of FIGS. 8B, 13A to 13C and 18A, B.

FIG. 20A shows that in some embodiments, an end configuration 900 of a conductive pin or wire 230 can include the end of the pin or wire 230 being approximately flush with or recessed with respect to the outer surface of the respective terminal 204.

It is noted that in some embodiments, a pin or wire can extend out of the outer surface of the respective terminal. Such an extension of the pin or wire can provide a stand-off from the packaged device that can be utilized to inspect, for example, solder joints associated with the packaged device.

FIG. 20B shows that in some embodiments, an end configuration 900 of a conductive pin or wire 230 can include the end of the pin or wire 230 being extended along its original direction. Such a configuration can provide a desired stand-off portion of the pin or wire 230 above the respective terminal 204.

FIG. 20C shows that in some embodiments, an end configuration 900 of a conductive pin or wire 230 can include the end of the pin or wire 230 being extended laterally outward from its original lateral location. Accordingly, such a configuration can include a bend (e.g., approximately 90 degrees) to provide a lateral stand-off portion from the respective terminal 204. In some embodiments, such a lateral stand-off portion may or may not extend beyond the lateral edge of the packaged device.

In the example of FIG. 20C, the lateral stand-off portion of the pin or wire 230 can be close to or in contact with the respective terminal 204. In some embodiments, it may be desirable to have an offset-portion that is above the respective terminal (such as in the example of FIG. 20B) and laterally extend outward (such as in the example FIG. 20C). Thus, FIG. 20D shows that in some embodiments, an end configuration 900 of a conductive pin or wire 230 can include the end of the pin or wire 230 having an extension in its original direction, as well as a laterally outward extension from its original lateral location. Such a configuration can provide a desired stand-off portion of the pin or wire 230 above and laterally outward from the respective terminal 204.

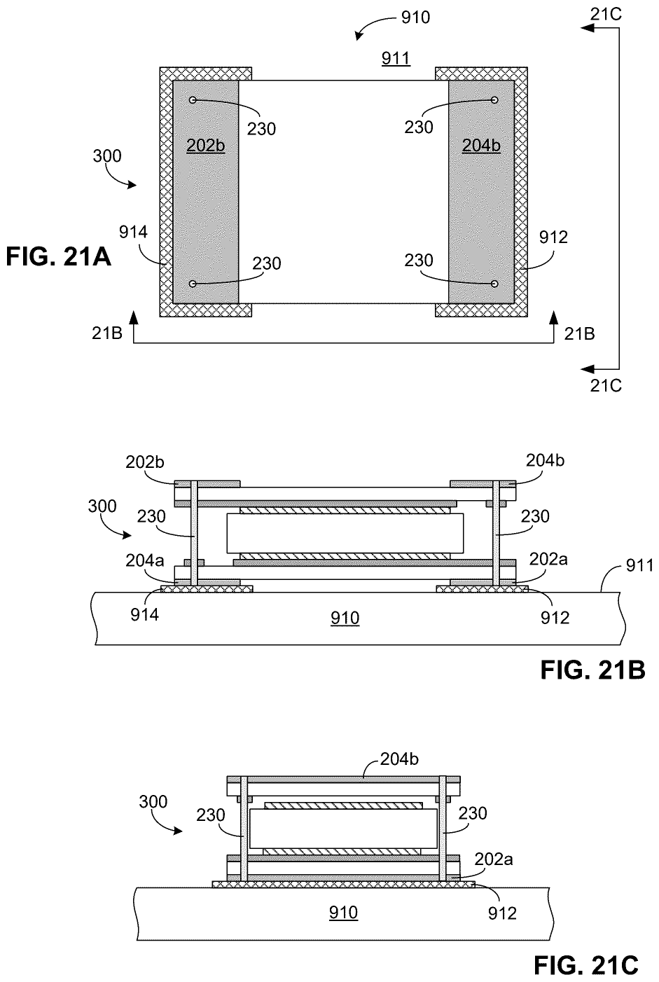

In some embodiments, a packaged device having one or more features as described herein can be mounted on a circuit board. FIGS. 21 to 24 show non-limiting examples of mounting configurations that can be implemented with packaged devices as described herein.

For example, FIGS. 21A to 21C show a mounting configuration where a packaged device 300 is surface mounted onto mounting pads 912, 914 implemented on an upper surface 911 (when viewed as in FIG. 21B or 21C) of a circuit board 910. More particularly, FIG. 21A shows a plan view of the mounting configuration from above the circuit board 910; FIG. 21B shows a side view as indicated in FIG. 21A; and FIG. 21C shows an end view as indicated in FIG. 21A.

Referring to FIGS. 21A to 21C, the packaged device 300 is shown to be positioned over the mounting pads 912, 914 so that a respective pair of terminals on one side of the packaged device 300 are in contact therewith. For example, the terminal 202a that is electrically connected to the lower electrode of the electrical device is shown to be in contact with the mounting pad 912, and the terminal 204a that is electrically connected to the upper electrode of the electrical device is shown to be in contact with the other mounting pad 914. It will be understood that such contacts between the terminals 202, 204a and their respective mounting pads 912, 914 can be secured by, for example, a soldering process.

In the example of FIGS. 21A to 21C, and assuming that the packaged device 300 has an overall height that is less than either of the overall lateral dimensions, the foregoing mounting configuration can provide a low-height profile of the mounted packaged device.

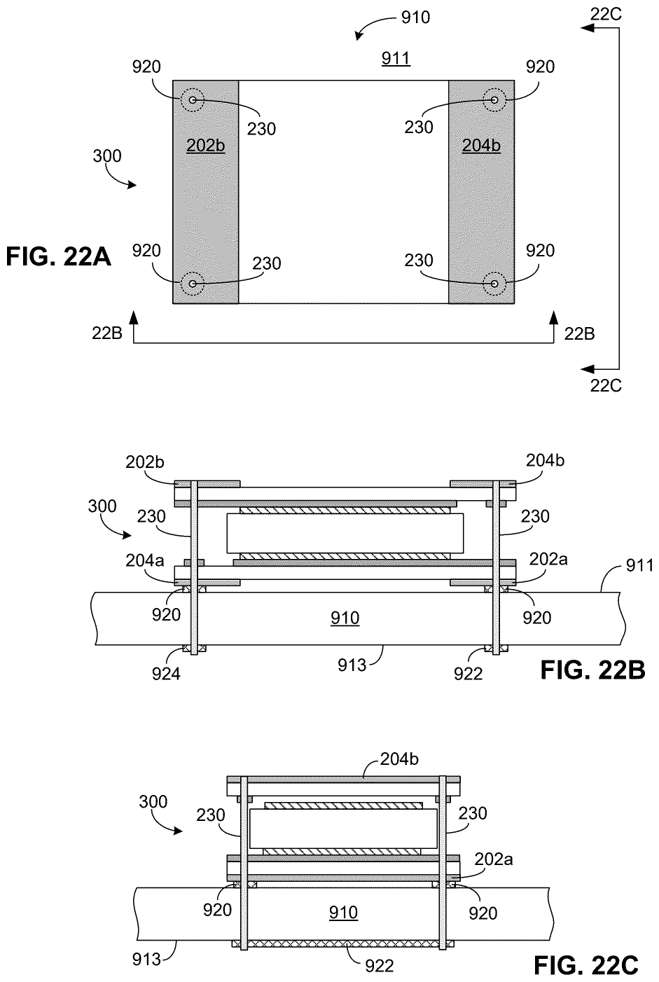

In some applications, it may be desirable to have a packaged device be mounted to provide the foregoing low-height profile, and also be able to include backside soldering to, for example, allow inspection of joints from the lower side of the circuit board. FIGS. 22A to 22C show an example that can provide the foregoing mounting configuration, where a packaged device 300 is positioned over mounting locations 920 implemented on an upper surface 911 (when viewed as in FIG. 22B or 22C) of a circuit board 910, and soldering to secure the packaged device onto the circuit board 910 includes soldering of conductive pins or wires 230 to respective solder pads 922, 924. More particularly, FIG. 22A shows a plan view of the mounting configuration from above the circuit board 910; FIG. 22B shows a side view as indicated in FIG. 22A; and FIG. 22C shows an end view as indicated in FIG. 22A.

Referring to FIGS. 22A to 22C, the packaged device 300 is shown to be positioned over the mounting locations 920 (e.g., conductive patterns) so that a respective pair of terminals on one side of the packaged device 300 are in contact therewith. For example, the terminal 202a that is electrically connected to the lower electrode of the electrical device is shown to be in contact with the mounting locations 920 on the right side of FIG. 22B, and the terminal 204a that is electrically connected to the upper electrode of the electrical device is shown to be in contact with the other mounting locations 920 on the left side of FIG. 22B. It will be understood that the mounting locations 920 on the right side of FIG. 22B may or may not be electrically connected with each other; similarly, the mounting locations 920 on the left side of FIG. 22B may or may not be electrically connected with each other.

Referring to FIGS. 22B and 22C, one can see that in some embodiments, each of the four example conductive pins or wires 230 can be configured to extend through the respective mounting location 920, the circuit board, and a respective soldering pad (922 or 924) implemented on the lower side 913 of the circuit board, so as to allow soldering of the conductive pin or wire 230 to the soldering pad (922 or 924) and inspection of the solder from the lower side 913.

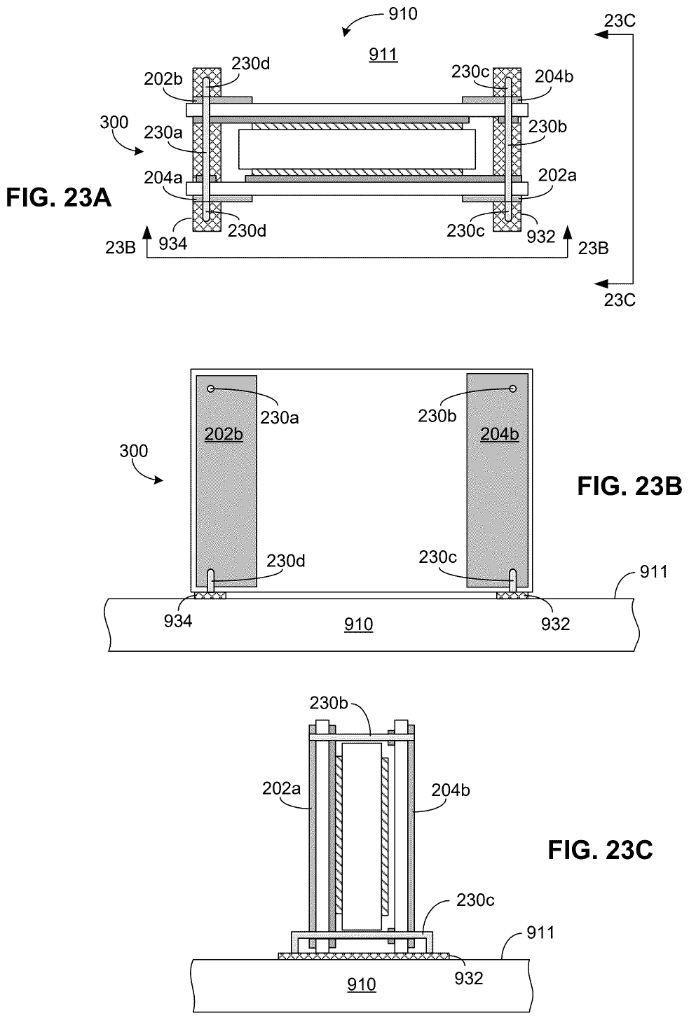

In some applications, it may be desirable to have a packaged device be mounted to provide a smaller footprint on a circuit board, but not necessarily a low-height profile. FIGS. 23A to 23C show an example that can provide the foregoing mounting configuration, where a packaged device 300 is positioned on its side over mounting pads 932, 934 implemented on an upper surface 911 (when viewed as in FIG. 23B or 23C) of a circuit board 910, and soldering to secure the packaged device onto the circuit board 910 includes soldering of conductive pins or wires 230c, 230d to respective mounting pads 932, 934. More particularly, FIG. 23A shows a plan view of the mounting configuration from above the circuit board 910; FIG. 23B shows a side view as indicated in FIG. 23A; and FIG. 23C shows an end view as indicated in FIG. 23A.

Referring to FIGS. 23A to 23C, the packaged device 300 is shown to be positioned on its side over the mounting pads 932, 934 so that the conductive pin or wire 230c near the right edge (when viewed as in FIG. 23B) and near the mounting side of the packaged device 300 engages the right mounting pad 932, and the conductive pin or wire 230d near the left edge (when viewed as in FIG. 23B) and near the mounting side of the packaged device 300 engages the left mounting pad 934. Thus, the terminals 202a, 204b that are electrically connected to the lower electrode of the electrical device are shown to be in electrical contact with the mounting pad 932 on the right side of FIG. 23B through the L-shaped ends of the conductive pin 230c, and the terminals 202b, 204a that are electrically connected to the upper electrode of the electrical device are shown to be in electrical contact with the mounting pad 934 on the left side of FIG. 23B through the L-shaped ends of the conductive pin 230d.

In the example of FIGS. 23A to 23C, the L-shaped ends of the conductive pins or wires 230c, 230d can be formed similar to the examples of FIGS. 20C and 20D. For example, each of the pins or wires 230c, 230d can extend just sufficiently to form an L-extension close to or touching the respective terminal (as in FIG. 20C), or extend further away from the respective terminal before forming an L-extension further away from the respective terminal (as in FIG. 20D). In either case, the L-extension can be dimensioned to allow formation of a secure solder contact when the mounting side of the packaged device 300 is positioned on the terminals 932, 934.

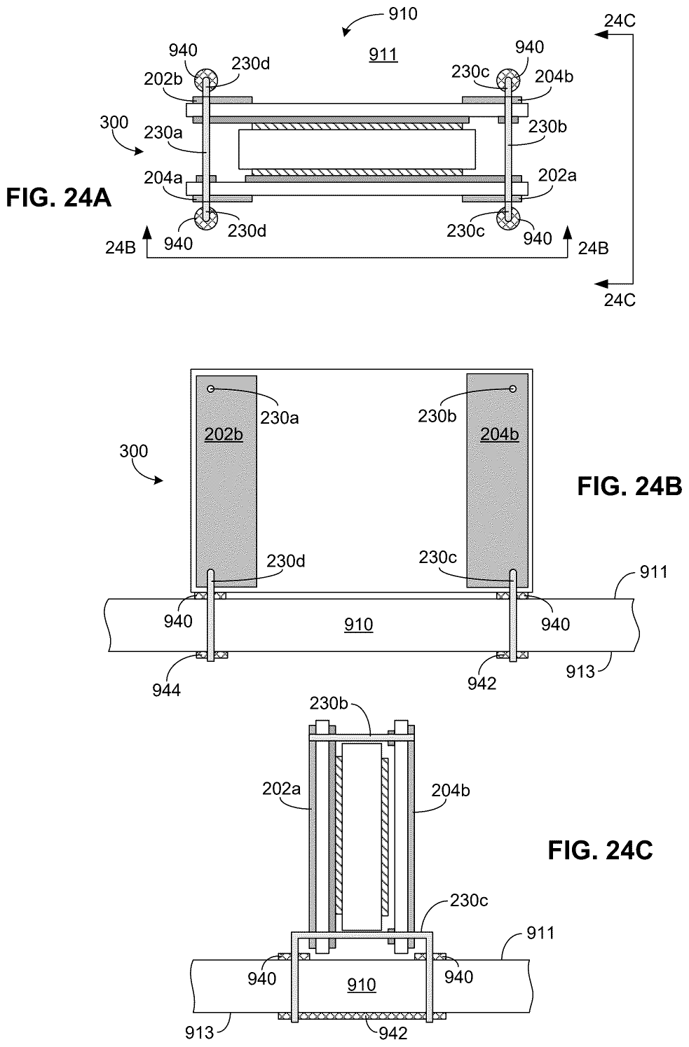

Similar to the example of FIGS. 22A to 22C, in some applications, it may be desirable to have a packaged device be mounted to include backside soldering to, for example, allow inspection of joints from the lower side of the circuit board. FIGS. 24A to 24C show an example that can provide the foregoing mounting configuration and with the smaller-footprint configuration similar to the example of FIGS. 23A to 23C. In FIGS. 24A to 24C a packaged device 300 is positioned over mounting locations 940 implemented on an upper surface 911 (when viewed as in FIG. 24B or 24C) of a circuit board 910, and soldering to secure the packaged device onto the circuit board 910 includes soldering of conductive pins or wires 230c, 230d to respective solder pads 942, 944. More particularly, FIG. 24A shows a plan view of the mounting configuration from above the circuit board 910; FIG. 24B shows a side view as indicated in FIG. 24A; and FIG. 24C shows an end view as indicated in FIG. 24A.

Referring to FIGS. 24A to 24C, the packaged device 300 is shown to be positioned on its side on an upper side 911 of the circuit board 910. With the foregoing orientation of the packaged device 300, the conductive pin or wire 230c near the right edge (when viewed as in FIG. 24B) and near the mounting side of the packaged device 300 extends through conductive patterns 940, through the circuit board 910, and through a terminal 942 on the right side (in FIG. 24B). Similarly, the conductive pin or wire 230d near the left edge (when viewed as in FIG. 24B) and near the mounting side of the packaged device 300 extends through conductive patterns 940, through the circuit board 910, and through a terminal 944 on the left side (in FIG. 24B). Thus, the terminals 202a, 204b (of the packaged device 300) that are electrically connected to the lower electrode of the electrical device are shown to be in electrical contact with the underside terminal 942 (of the circuit board 910) on the right side of FIG. 24B through the L-shaped ends of the conductive pin 230c, and the terminals 202b, 204a (of the packaged device 300) that are electrically connected to the upper electrode of the electrical device are shown to be in electrical contact with the underside terminal 944 (of the circuit board 910) on the left side of FIG. 24B through the L-shaped ends of the conductive pin 230d.

In the example of FIGS. 24A to 24C, the L-shaped ends of the conductive pins or wires 230c, 230d can be formed similar to the examples of FIGS. 20C and 20D. For example, each of the pins or wires 230c, 230d can extend just sufficiently to form an L-extension close to or touching the respective terminal (as in FIG. 20C), or extend further away from the respective terminal before forming an L-extension further away from the respective terminal (as in FIG. 20D). In either case, the L-extension can be dimensioned to allow its extension through the circuit board 910 and allow formation of a secure solder contact with the respective underside terminal (942 or 944).

In the mounting configuration examples of FIGS. 21 to 24, it is assumed that the packaged devices 300 have respective electrical devices with two opposing electrodes. However, it will be understood that in some embodiments, packaged devices with electrical devices with more than two electrodes, such as the examples of FIGS. 16 to 18, can also be mounted on circuit boards in similar manners.

Also, in the examples of FIGS. 21 to 24, ends of conductive pins or wires on the non-mounting side or edge are depicted as being generally flush with their respective terminals. However, it will be understood that in some embodiments, some or all of such ends can be configured with extensions, such as the example extensions of FIGS. 19 and 20, to provide, for example, inspection functionality.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged device comprising:
an electrical device having first and second electrodes implemented on opposite sides of a body;
a first terminal assembly including a substrate having an inner side and an outer side, a conductive feature on the inner side of the substrate and first and second terminals on the outer side of the substrate;
a second terminal assembly including a substrate having an inner side and an outer side, a conductive feature on the inner side of the substrate and first and second terminals on the outer side of the substrate;
wherein the electrical device is sandwiched between the first and second terminal assemblies to provide first and second spaces each defined between the inner sides of the substrates of the first and second terminal assemblies and a respective lateral side of the electrical device, such that the conductive features of the first and second terminal assemblies are electrically connected with the first and second electrodes of the electrical device, respectively; and
a set of conductive pins or wires including a first conductive pin or wire extending through the first space to join the respective portions of the first and second terminal assemblies, such that the first electrode of the electrical device is electrically connected to the first terminal of the first terminal assembly and the second terminal of the second terminal assembly through the conductive feature of the first terminal assembly and the first conductive pin or wire, the set of conductive pins or wires further including a second conductive pin or wire extending through the second space to join the respective portions of the first and second terminal assemblies, such that the second electrode of the electrical device is electrically connected to the second terminal of the first terminal assembly and the first terminal of the second terminal assembly through the conductive feature of the second terminal assembly and the second conductive pin or wire.

2. The packaged device of claim 1, wherein the electrical device further includes a third electrode implemented on the side of the body with the first electrode, the first terminal assembly further includes a second conductive feature on the inner side of the substrate and a third terminal on the outer side of the substrate, the second terminal assembly further includes a third terminal on the outer side of the substrate, and the set of pins or wires further includes a third conductive pin or wire extending through the first space to join the respective portions of the first and second terminal assemblies, such that the third electrode of the electrical device is electrically connected to the third terminal of the first terminal assembly and the third terminal of the second terminal assembly through the second conductive feature of the first terminal assembly and the third conductive pin or wire.

3. The packaged device of claim 1, wherein the first and second spaces are parts of a contiguous space that surrounds the electrical device, such that the first and second spaces are at or near opposing ends of the packaged device.

4. The packaged device of claim 3, further comprising an electrical insulator filler material that fills at least portions of the contiguous space to substantially encapsulate the lateral periphery of the electrical device and the set of conductive pins or wires.

5. The packaged device of claim 1, wherein the first and second electrodes of the electrical device are substantially parallel to each other, and the substrates of the first and second terminal assemblies are also substantially parallel to each other.

6. The packaged device of claim 5, wherein each of the substrates of the first and second terminal assemblies has a rectangular shape.

7. The packaged device of claim 6, wherein the conductive feature of each of the first and second terminal assemblies includes an electrode-contact portion and an edge portion in electrical contact with the electrode-contact portion, the edge portion implemented to be at or near a first edge of the respective substrate, and the electrode-contact portion implemented to be laterally closer to a center of the substrate.

8. The packaged device of claim 7, wherein the edge portion includes a hole configured to allow the respective conductive pin or wire to pass therethrough.

9. The packaged device of claim 8, wherein the hole extends through the substrate and the respective terminal on the other side of the substrate.

10. The packaged device of claim 9, wherein the hole includes a conductive wall.

11. The packaged device of claim 7, wherein the conductive feature has a rectangular shape with one edge being at or near the first edge.

12. The packaged device of claim 7, wherein the electrode-contact portion of the conductive portion is dimensioned to promote desired lateral positioning of the electrical device during a mounting operation.

13. The packaged device of claim 12, wherein the electrode-contact portion includes a shape that is similar to a shape of the respective electrode of the electrical device.

14. The packaged device of claim 13, wherein the electrode of the electrical device has a circular shape, and the electrode-contact portion of the conductive feature includes at least a portion of a circular boundary.

15. The packaged device of claim 7, wherein the set of conductive pins or wires further includes a third conductive pin or wire extending through the first space to provide an electrical connection similar to the first conductive pin or wire, and a fourth conductive pin or wire extending through the second space to provide an electrical connection similar to the second conductive pin or wire.

16. The packaged device of claim 15, wherein the first, second, third and fourth conductive pins or wires are positioned near respective corners of the rectangular shaped substrates.

17. The packaged device of claim 15, wherein some or all of the first, second, third and fourth conductive pins or wires include respective ends that extend beyond respective terminal(s) and configured to support mounting of the packaged device on a circuit board and/or inspection of the mounted packaged device.

18. The packaged device of claim 17, wherein the ends of the conductive pins or wires configured to support mounting of the packaged device include an extension along the same direction of the respective conductive pin or wire between the first and second terminal assemblies, the extension dimensioned to allow formation of electrical contacts with a respective terminal on the side opposite from the mounting side of the circuit board.

19. The packaged device of claim 18, wherein the first terminal assembly of the packaged device faces the mounting side of the circuit board.

20. The packaged device of claim 17, wherein the ends of the conductive pins or wires configured to support mounting of the packaged device include an L-shaped extension with respect to the direction of the respective conductive pin or wire between the first and second terminal assemblies.

21. The packaged device of claim 20, wherein the edge of the packaged device including the first and second terminals of each terminal assembly faces the mounting side of the circuit board.

22. The packaged device of claim 21, wherein the L-shaped extension is dimensioned to allow formation of electrical contacts with a respective terminal on the mounting side of the circuit board.

23. The packaged device of claim 21, wherein the L-shaped extension is dimensioned to allow formation of electrical contacts with a respective terminal on the side opposite from the mounting side of the circuit board.

24. The packaged device of claim 5, further comprising an insulator sleeve that substantially covers the portion of each conductive pin or wire in the respective space.

25. The packaged device of claim 24, wherein the insulator sleeve is configured to reduce and/or mitigate thermal expansion mismatch associated with the respective conductive pin or wire, and/or to provide improved handling of a voltage operating condition.

26. The packaged device of claim 5, wherein each terminal assembly further includes an electrical insulator layer implemented on the outer side of the respective substrate to cover some or all of an area between the respective terminals.

27. The packaged device of claim 26, wherein the electrical insulator layer includes a surface configured to allow marking thereon.

28. The packaged device of claim 27, wherein the electrical insulator layer includes a solder mask material.

29. The packaged device of claim 5, wherein some or all edges of each substrate includes a score feature surface resulting from singulation of the packaged device from an array of similar packaged devices.

30. The packaged device of claim 1, wherein the first and second terminal assemblies are configured substantially the same, such that when the electrical device is sandwiched between the first and second terminal assemblies, one terminal assembly is rotated approximately 180 degrees with respect to the other terminal assembly.

31. A method for fabricating a packaged device, the method comprising:
forming or providing an electrical device having first and second electrodes implemented on opposite sides of a body;
forming or providing a first terminal assembly including a substrate having an inner side and an outer side, a conductive feature on the inner side of the substrate and first and second terminals on the outer side of the substrate;
forming or providing a second terminal assembly including a substrate having an inner side and an outer side, a conductive feature on the inner side of the substrate and first and second terminals on the outer side of the substrate;
assembling the electrical device and the first and second terminal assemblies such that the electrical device is sandwiched between the first and second terminal assemblies to provide first and second spaces each defined between the inner sides of the substrates of the first and second terminal assemblies and a respective lateral side of the electrical device, such that the conductive features of the first and second terminal assemblies are electrically connected with the first and second electrodes of the electrical device, respectively; and
installing a set of conductive pins or wires including a first conductive pin or wire extending through the first space to join the respective portions of the first and second terminal assemblies, such that the first electrode of the electrical device is electrically connected to the first terminal of the first terminal assembly and the second terminal of the second terminal assembly through the conductive feature of the first terminal assembly and the first conductive pin or wire, the set of conductive pins or wires further including a second conductive pin or wire extending through the second space to join the respective portions of the first and second terminal assemblies, such that the second electrode of the electrical device is electrically connected to the second terminal of the first terminal assembly and the first terminal of the second terminal assembly through the conductive feature of the second terminal assembly and the second conductive pin or wire.

32. A method for fabricating packaged devices, the method comprising:
providing or forming first and second terminal assembly panels each having an array of units, each unit including a substrate having an inner side and an outer side, a conductive feature on the inner side, and first and second terminals on the outer side of the substrate;
mounting an electrical device having first and second electrodes implemented on opposite sides of a body on each unit of the first terminal assembly panel, such that the first electrode of the electrical device is electrically connected to the conductive feature of the respective unit of the first terminal assembly panel;
mounting the second terminal assembly panel over the array of electrical devices, such that the second electrode of each electrical device is electrically connected to the conductive feature of the respective unit of the second terminal assembly panel, the mounting of the second terminal assembly panel resulting in each electrical device being sandwiched between the respective units of the first and second terminal assembly panels to provide first and second spaces each defined between the inner sides of the respective substrates and a respective lateral side of the electrical device;
installing a set of conductive pins or wires for each unit, the set of conductive pins or wires including a first conductive pin or wire extending through the first space to join the respective portions of the first and second terminal assemblies, such that the first electrode of the electrical device is electrically connected to the first terminal of the first terminal assembly and the second terminal of the second terminal assembly through the conductive feature of the first terminal assembly and the first conductive pin or wire, the set of conductive pins or wires further including a second conductive pin or wire extending through the second space to join the respective portions of the first and second terminal assemblies, such that the second electrode of the electrical device is electrically connected to the second terminal of the first terminal assembly and the first terminal of the second terminal assembly through the conductive feature of the second terminal assembly and the second conductive pin or wire; and
singulating the sandwich-pair of units to provide a plurality of individual sandwich-pair of units.
